(19) United States
(12) Patent Application Publication
(10) Pub. No.: US 2026/0210759 A1
(43) Pub. Date: Jul. 23, 2026

(54) PHOTODETECTOR AND CONTROL METHOD OF PHOTODETECTOR

(71) Applicant: Samsung Electronics Co., Ltd., Suwon-si (KR)

(72) Inventors: Junpei Tanaka, Yokohama (JP); Fumiya Saitoh, Yokohama (JP)

(21) Appl. No.: 19/449,539

(22) Filed: Jan. 15, 2026

(30) Foreign Application Priority Data
Jan. 20, 2025 (JP) 2025-007476

(51) Int. Cl. G01J 1/44; H10F 39/00; H10F 39/18

(52) U.S. Cl. CPC G01J 1/44; H10F 39/014; H10F 39/18; G01J 2001/442; G01J 2001/444; G01J 2001/4466; G01J 2001/448

(57) ABSTRACT

Provided is a photodetector which includes a plurality of photoelectric conversion devices, wherein the photoelectric conversion device includes a cathode electrode, an anode electrode arranged around the cathode electrode, an electron multiplication region in which a first region of a first conductivity type is bonded to a second region of a second conductivity type, a voltage transfer region of the first conductivity type arranged around the cathode electrode and configured to transfer a voltage of the anode electrode to the first region of the electron multiplication region, and a gate electrode arranged around the cathode electrode and facing the voltage transfer region with an insulating film arranged therebetween, wherein a degree of voltage transfer from the voltage transfer region to the first region is adjusted by a gate voltage applied to the gate electrode.

### CROSS-REFERENCE TO RELATED APPLICATION

This application claims the benefit of Japanese Patent Application No. 2025-007476, filed on January 20, 2025, in the Japanese Patent Office, the disclosures of which are incorporated by reference herein in their entireties.

### BACKGROUND

The present invention relates to a photodetector and a control method of the photodetector.

Recently, a single-photon avalanche diode (SPAD), which multiplies a charge generated by photoelectric conversion of incident light through avalanche multiplication and outputs the charge as an electric signal, has attracted attention. The SPAD has an extremely high time resolution, making it is possible to detect particles of light one by one.

An SPAD device generates an avalanche current when photons are incident in a state in which a reverse bias voltage equal to or greater than a breakdown voltage is applied between an anode and a cathode. By increasing the applied voltage, the multiplication probability increases, resulting in improved photodetection sensitivity of the SPAD device. However, a dark count rate (DCR) is increased, and the photodetection accuracy of the SPAD device is degraded by increasing the applied voltage. This is mainly due to the following two reasons. One reason is that, as the voltage applied to a multiplication region between the anode and the cathode of the SPAD device increases, a tunnel current due to Zener breakdown in the multiplication region of the SPAD device increases. Another reason is that an electric field outside the multiplication region between the anode and the cathode of the SPAD device also increases, resulting in edge breakdown.

In some photodetectors, provided are a first semiconductor region of a first conductivity type, a third semiconductor region of the first conductivity type, and a second semiconductor region of a second conductivity type between the first semiconductor region and the third semiconductor region. By controlling a potential applied to the third semiconductor region, a potential barrier having a height that does not cause avalanche multiplication with respect to a signal charge in the first semiconductor region is formed in the second semiconductor region, and the signal charge is accumulated in the first semiconductor region. Thereafter, the signal charge accumulated in the first semiconductor region is transferred to the third semiconductor region by lowering the height of the potential barrier.

### SUMMARY

In photodetectors discussed above, it is necessary to increase the voltage applied between an anode and a cathode to increase the multiplication probability of a photodetector. However, a problem may arise in that increasing the voltage applied between the anode and the cathode may cause edge breakdown outside the multiplication region between the anode and cathode, resulting in an increased dark count rate (DCR) and degraded photodetection accuracy.

The inventive concept has been made to address the above issues. Example embodiments of the inventive concept provide a photodetector and a control method of the photodetector, which can improve photodetection sensitivity, without increasing the DCR, while reducing manufacturing variations in photodetection sensitivity.

The photodetector includes a plurality of photoelectric conversion devices, wherein each of the photoelectric conversion device includes: a cathode electrode; an anode electrode arranged around the cathode electrode; an electron multiplication region comprising a first region of a first conductivity type is in contact with a second region of a second conductivity type; a voltage transfer region of the first conductivity type arranged around the cathode electrode and configured to transfer a voltage of the anode electrode to the first region of the electron multiplication region; and a gate electrode arranged around the cathode electrode and facing the voltage transfer region with an insulating film arranged between the gate electrode and the cathode electrode, wherein a degree of voltage transfer from the voltage transfer region to the first region is adjustable based on a gate voltage applied to the gate electrode.

In one example embodiment, a photodetector includes a plurality of photoelectric conversion devices, wherein each of the photoelectric conversion devices comprises: a cathode electrode; an anode electrode arranged around the cathode electrode; an electron multiplication region comprising a first region of a first conductivity type in contact with a second region of a second conductivity type; a voltage transfer region of the first conductivity type arranged around the cathode electrode and configured to transfer a voltage of the anode electrode to the first region of the electron multiplication region; a gate electrode arranged around the cathode electrode and facing the voltage transfer region with an insulating film arranged therebetween; and a gate voltage controller configured to adjust a gate voltage applied to the gate electrode, based on one or more of a detected temperature of the photoelectric conversion device, a dark count rate (DCR) of the photoelectric conversion device, and an amount of light around the photoelectric conversion device, wherein a degree of voltage transfer from the voltage transfer region to the first region is adjustable based on the gate voltage applied to the gate electrode.

In at least one example embodiment, a control method of a photodetector including a plurality of photoelectric conversion devices, wherein each of the photoelectric conversion device includes a cathode electrode; an anode electrode arranged around the cathode electrode; an electron multiplication region comprising a first region of a first conductivity type in contact with a second region of a second conductivity type; a voltage transfer region of the first conductivity type arranged around the cathode electrode and configured to transfer a voltage of the anode electrode to the first region of the electron multiplication region; and a gate electrode arranged around the cathode electrode and facing the voltage transfer region with an insulating film arranged therebetween, wherein a degree of voltage transfer from the voltage transfer region to the first region is adjusted by a gate voltage applied to the gate electrode, the control method including:(a) detecting: a temperature of a first photoelectric conversion device of the plurality of photoelectric conversion devices, a dark count rate (DCR) of the first photoelectric conversion device, and/or an amount of light around the first photoelectric conversion device; and (b) adjusting the gate voltage, based on: the detected temperature of the first photoelectric conversion device, the detected DCR of the first photoelectric transfer device, and/or the detected amount of light around the first photoelectric conversion device.

### BRIEF DESCRIPTION OF THE DRAWINGS

Embodiments will be more clearly understood from the following detailed description taken in conjunction with the accompanying drawings in which:

FIG. 1 is a schematic block diagram of an image sensor;

FIG. 2 is a schematic circuit diagram of a single-photon avalanche diode (SPAD) pixel;

FIG. 3 is a diagram illustrating a stacked structure of an image sensor;

FIG. 4 is a cross-sectional view of a single SPAD device;

FIG. 5A is a cross-sectional view of multiple adjacent SPAD devices;

FIG. 5B is a plan view of multiple adjacent SPAD devices;

FIG. 5C is a plan view of multiple adjacent SPAD devices;

FIG. 5D is a plan view of multiple adjacent SPAD devices;

FIG. 6 is a graph of potential with respect to distance in a depth direction of a substrate along a dashed-dotted line arrow in FIG. 4;

FIG. 7A is a diagram illustrating a potential distribution at each position in a substrate when a gate voltage is applied to a gate electrode;

FIG. 7B is a diagram illustrating a potential distribution at each position in a substrate having a conventional structure without a gate electrode;

FIG. 8 is a graph of potential with respect to distance in a depth direction of a substrate, along the dashed-dotted line arrow in FIG. 4, showing a difference in potential depending on whether a gate voltage is applied to a gate electrode;

FIG. 9 is a graph of electric field with respect to distance in a depth direction of a substrate, along the dashed-dotted line arrow in FIG. 4, showing a difference in electric field depending on whether a gate voltage is applied to a gate electrode;

FIG. 10 is a graph of multiplication probability with respect to distance in a depth direction of a substrate, along the dashed-dotted line arrow in FIG. 4, showing a difference in multiplication probability depending on whether a gate voltage is applied to a gate electrode;

FIG. 11 is a cross-sectional view illustrating a method of manufacturing an image sensor;

FIG. 12 is a cross-sectional view illustrating a method of manufacturing an image sensor;

FIG. 13 is a cross-sectional view illustrating a method of manufacturing an image sensor;

FIG. 14 is a cross-sectional view illustrating a method of manufacturing an image sensor;

FIG. 15 is a cross-sectional view illustrating a method of manufacturing an image sensor;

FIG. 16 is a cross-sectional view illustrating a method of manufacturing an image sensor;

FIG. 17 is a cross-sectional view illustrating a method of manufacturing an image sensor;

FIG. 18 is a cross-sectional view illustrating a method of manufacturing an image sensor;

FIG. 19 is a cross-sectional view illustrating a method of manufacturing an image sensor;

FIG. 20 is a flowchart illustrating main processes of a method of manufacturing an image sensor;

FIG. 21 is configuration diagram of a system including an SPAD device and an output circuit;

FIG. 22 is a flowchart of a control method of an image sensor for adjusting a gate voltage;

FIG. 23 is a configuration diagram of a system including an SPAD device and an output circuit;

FIG. 24 is a circuit diagram of a gate voltage generator;

FIG. 25 is a configuration diagram of a system including an SPAD device and an output circuit;

FIG. 26 is a cross-sectional view of a single SPAD device;

FIG. 27 is a cross-sectional view of a single SPAD device;

FIG. 28 is a cross-sectional view of a single SPAD device;

FIG. 29 is a diagram showing that electrons multiplied in an electron multiplication region are discharged through an N-type contact layer;

FIG. 30 is a cross-sectional view of a single SPAD device;

FIG. 31 is a cross-sectional view of a single SPAD device; and

FIG. 32 is a cross-sectional view of a single SPAD device.

### DETAILED DESCRIPTION OF THE EMBODIMENTS

Hereinafter, a photodetector and a control method of the photodetector according to an embodiment are described in detail with reference to the drawings. The embodiments are merely examples and are subject to various modifications from these embodiments. Hereinafter, the same reference numerals in the drawings refer to the same components, and the size of each component in the drawings is expressed at different proportions from actual ones for clarity and convenience of description.

Hereinafter, the expressions such as “above” or “on” include not only cases where a component is in direct contact with another component at the upper/lower/left/right side, but also cases where the component is arranged at the upper/lower/left/right side without direct contact.

Terms, or ordinal adjectives such as “first” and “second”, are used to describe various components, but only for the purpose of distinguishing one component from another. These terms are not intended to limit the materials or structures of the components to others.

A component expressed in a singular form includes multiple components unless clearly stated otherwise. In addition, when a certain portion is described as “including” a certain component, it means that the portion does not exclude other components but rather may further include other components, unless specifically stated otherwise.

In addition, the term “unit” described herein refers to a unit processing one or more functions or operations, which is implemented by hardware or software, or implemented by a combination of hardware and software.

Hereinafter, for simplicity of description, a case where a first conductivity type is a P type and a second conductivity type is an N type is described as an example. However, this is for simplicity of description. The first conductivity type may be the N type, and the second conductivity type may be the P type. A case where a first conductivity-type semiconductor layer is a P-type semiconductor layer is described as an example. A case where a second conductivity-type semiconductor layer is an N-type semiconductor layer is described as an example. The first conductivity-type semiconductor layer may also be an N-type semiconductor layer. The second conductivity-type semiconductor layer may also be a P-type semiconductor layer.

The term "substrate" may denote a base substrate (e.g., an initial semiconductor substrate forming the base of the wafer in the final wafer product, such as a bulk semiconductor substrate (e.g., formed of crystalline silicon), an silicon on insulator (SOI) substrate, etc.), or a stack structure including such a base substrate and layers formed on the base substrate.

It will be understood that when an element is referred to as being "connected" or "coupled" to or “on” another element, it can be directly connected or coupled to or on the other element or intervening elements may be present. In contrast, when an element is referred to as being "directly connected" or "directly coupled" to another element, or as “contacting” or “in contact with” another element (or using any form of the word “contact”), there are no intervening elements present at the point of contact. As the state of contact is binary (either in contact or not in contact), it will be appreciated that “contact” has the same scope as any use of “direct contact.”

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

### First Embodiment

### Image Sensor 1

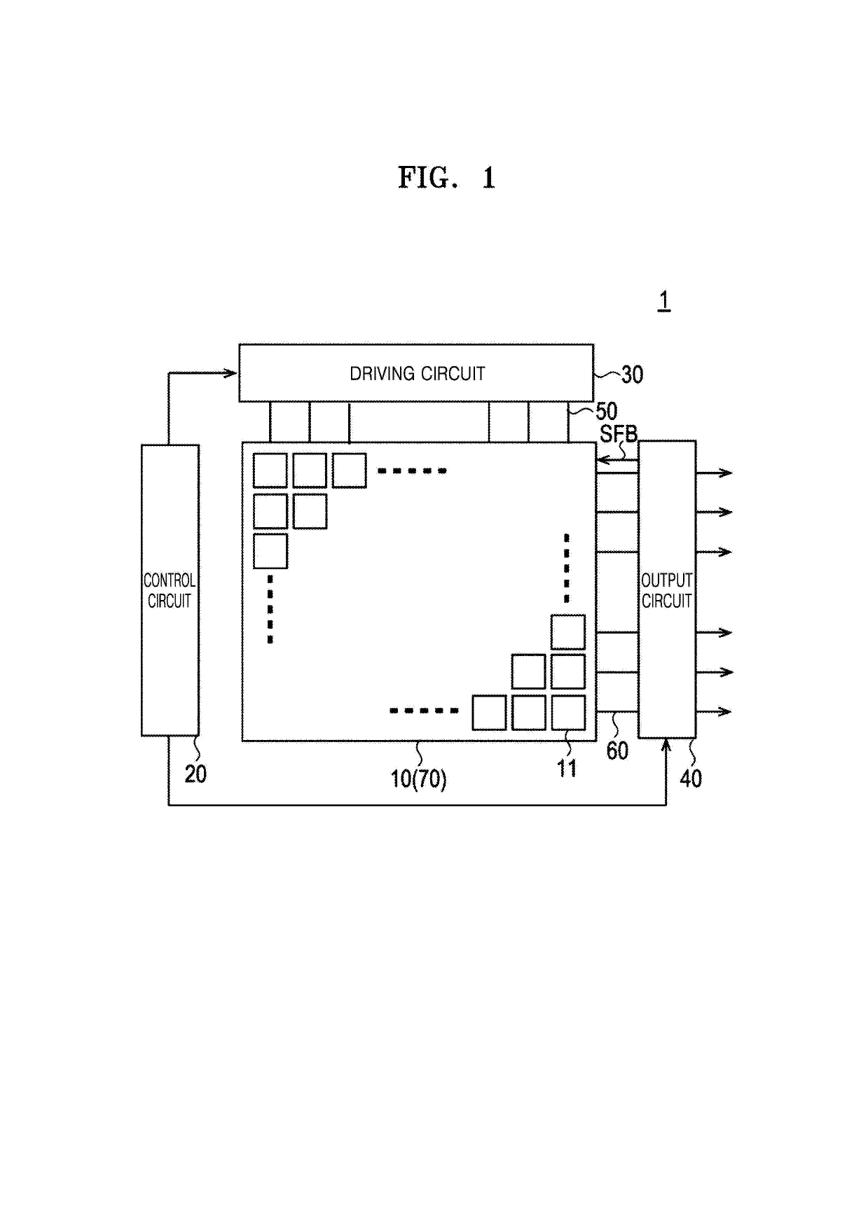

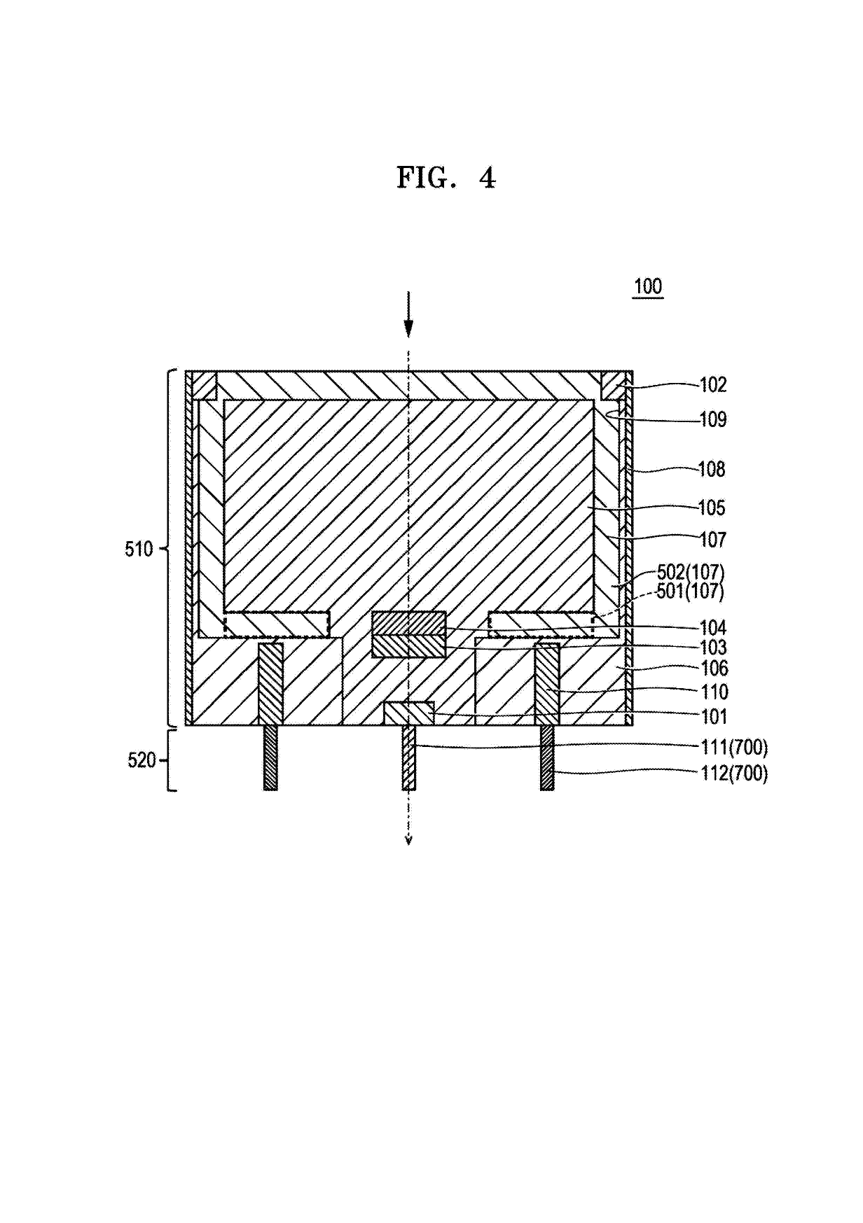

FIG. 1 is a schematic block diagram of an image sensor 1. The image sensor 1 may be, for example, a back-illuminated image sensor. The image sensor 1 may also be a front-illuminated image sensor. For example, as the back-illuminated image sensor, a surface opposite to a device-forming surface of a semiconductor substrate 510 (see FIG. 4) functions as a light incident surface. For example, as the front-illuminated image sensor, the device-forming surface functions as the light incident surface. Hereinafter, for simplicity of description, the image sensor 1 is described as the back-illuminated image sensor. In addition, the device-forming surface of the semiconductor substrate 510 is referred to as a “front surface”, and a surface opposite to the device-forming surface of the semiconductor substrate 510 as a “back surface”.

The image sensor 1 includes a pixel array 10, a control circuit 20, a driving circuit 30, and an output circuit 40. The image sensor 1 constitutes a photodetector.

The pixel array 10 includes a plurality of single-photon avalanche diode (SPAD) pixels 11 arranged in a matrix. A pixel drive line 50 is connected to each column of SPAD pixels 11, and an output signal line 60 is connected to each row of SPAD pixels 11. The pixel drive line 50 is connected to an output terminal of the driving circuit 30 corresponding to each column of SPAD pixels 11. The output signal line 60 is connected to an input terminal of the output circuit 40 corresponding to each row of SPAD pixels 11.

The driving circuit 30 includes a shift register or an address decoder and drives all the SPAD pixels 11 of the pixel array 10 simultaneously or on a column basis. The driving circuit 30 includes a circuit for applying a quench voltage VQ to be described below to each SPAD pixel 11. When driving the SPAD pixels 11 on a column basis, the driving circuit 30 may include a circuit that applies a selection signal voltage VSEL to each SPAD pixel 11 in a selected column of SPAD pixels 11. In this case, each SPAD pixel 11 is selected by the selection signal voltage VSEL, and a power supply voltage is applied only to the selected SPAD pixel 11 to output a detection signal VD from the SPAD pixel 11.

The detection signal VD output from each SPAD pixel 11 is input to the output circuit 40 through each output signal line 60. The output circuit 40 outputs the detection signal VD input from each SPAD pixel 11 as an image signal VOUT.

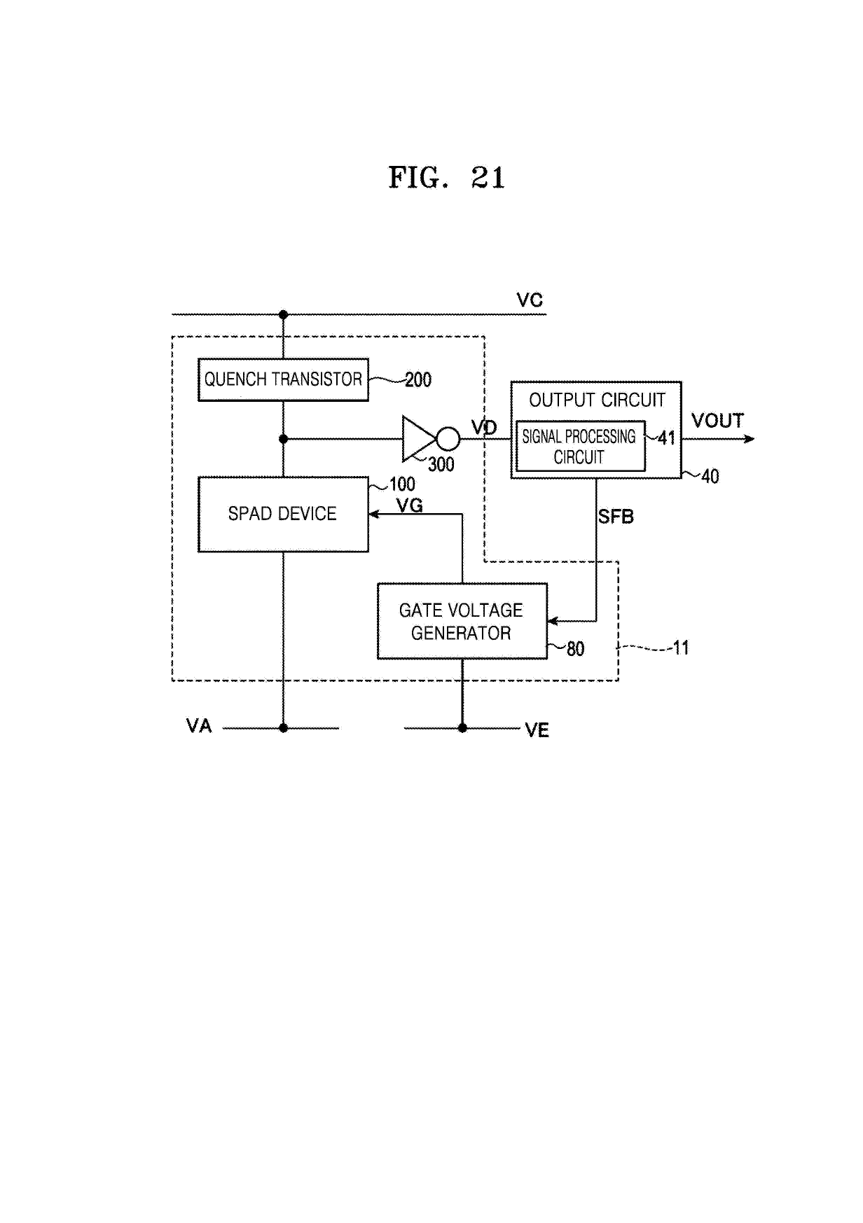

The output circuit 40 includes a signal processing circuit 41 (see FIG. 21) to be described below. The signal processing circuit 41 generates a feedback signal SFB, based on the detection signal VD, so that a gate voltage generator 80 (described below) of the SPAD pixel 11 generates a gate voltage VG. The feedback signal SFB may be input to each SPAD pixel 11 through a feedback signal line. The gate voltage VG is described below.

The control circuit 20 includes a timing generator that generates various timing signals and controls the driving circuit 30 and the output circuit 40 based on various timing signals generated by the timing generator.

### SPAD pixel 11

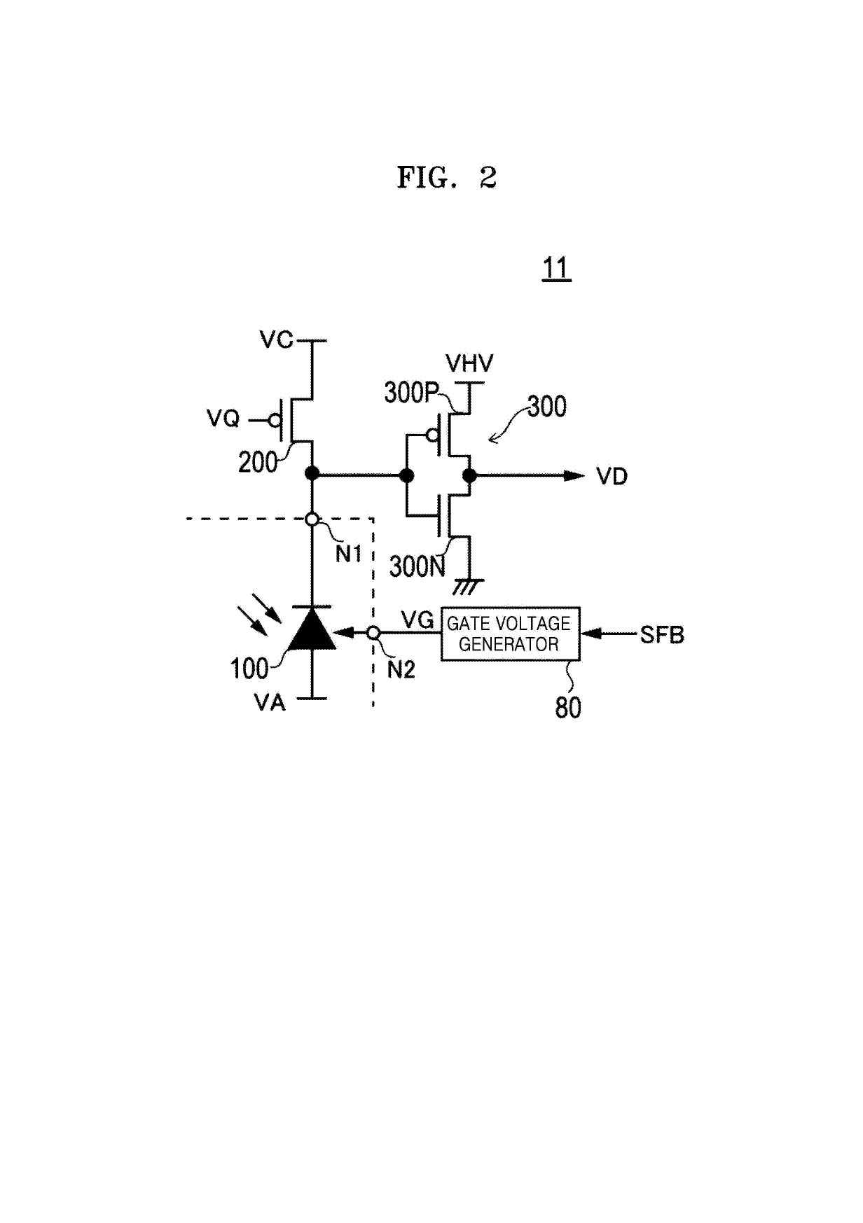

FIG. 2 is a schematic circuit diagram of the SPAD pixel 11.

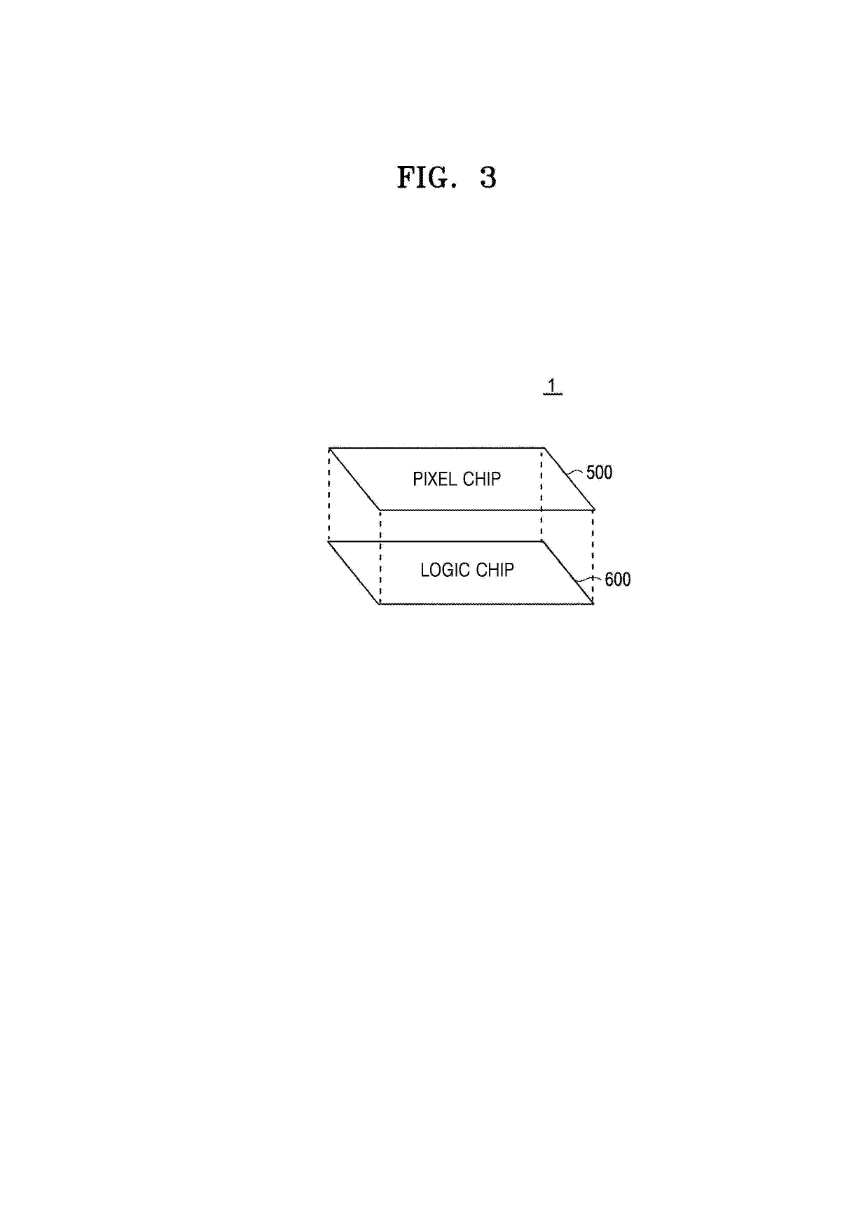

The SPAD pixel 11 includes a SPAD device 100, a quench transistor 200, an inverter 300, and a gate voltage generator 80. The SPAD device 100 constitutes a photoelectric conversion device. As described below, the SPAD device 100 may be formed in a pixel chip 500 (see FIG. 3), and the quench transistor 200, the inverter 300, and the gate voltage generator 80 may be formed in a logic chip 600. Each SPAD pixel is formed by bonding the pixel chip 500 to the logic chip 600 in positional alignment for each SPAD pixel 11. In FIG. 2, a junction where the SPAD device 100 is connected to the quench transistor 200 and a junction where the SPAD device 100 is connected to the gate voltage generator 80, formed by bonding the pixel chip 500 to the logic chip 600, are shown as a node N1 and a node N2, respectively. In addition, a boundary between the pixel chip 500 and the logic chip 600 is indicated by a dashed line.

The SPAD device 100, which is a light-receiving device, generates an avalanche current when photons are incident in a state where a reverse bias voltage VSPAD equal to or greater than the breakdown voltage is applied between an anode and a cathode. An anode voltage VA is applied to the anode of the SPAD device 100, and a cathode voltage VC is applied to the cathode of the SPAD device 100 through the quench transistor 200. The anode voltage VA is set to, e.g., about -15 V to about -30 V. The cathode voltage VC is set to, e.g., about 2 V to about 5 V. As the reverse bias voltage VSPAD equal to or greater than the breakdown voltage is applied between the anode and the cathode, the SPAD device 100 operates in a Geiger mode to detect one photon. The reverse bias voltage VSPAD is a sum of an absolute value of the anode voltage VA and an absolute value of the cathode voltage VC.

The quench transistor 200 is constituted by, for example, a P-channel metal oxide semiconductor (PMOS) transistor. The quench transistor 200 operates as a quench resistor when the quench voltage VQ supplied from the driving circuit 30 is applied to a gate thereof. In addition, the quench transistor 200 functions to perform a recharge operation that returns a voltage supplied to the SPAD device 100 to the cathode voltage VC by causing a current corresponding to a voltage drop in the quench operation to flow.

The current flowing through the SPAD device 100 is converted into a voltage by the quench transistor 200 and output to the inverter 300.

The inverter 300 is formed by connecting a PMOS transistor 300P to a N-channel metal oxide semiconductor (NMOS) transistor 300N in series. A source of the PMOS transistor 300P is connected to a power supply VHV for driving a digital circuit, and a drain of the PMOS transistor 300P is connected to a drain of the NMOS transistor 300N. The drain of the NMOS transistor 300N is connected to the drain of the PMOS transistor 300P, and a source of the NMOS transistor 300N is grounded. A gate of the PMOS transistor 300P is connected to a gate of the NMOS transistor 300N, and a junction thereof functions as an input of the inverter 300. A junction of the drain of the PMOS transistor 300P and the drain of the NMOS transistor 300N functions as an output of the inverter 300. The input of the inverter 300 is connected to the node N1 which is a junction of the SPAD device 100 and the quench transistor 200.

The inverter 300 converts the input voltage into a digital signal and outputs the same as the detection signal VD. In addition, by providing a buffer for impedance conversion to the output of the inverter 300, the detection signal VD subjected to impedance conversion may be output from each SPAD pixel 11.

The detection signal VD is input to the output circuit 40. For example, the output circuit 40 outputs the detection signal VD to a processor (not shown) via a time-to-digital converter (TDC) (not shown) in the case of a direct time of flight (dToF) system, and the output circuit 40 outputs the detection signal VD to the processor via a counter (not shown) in the case of a photon counting system. The detection signal VD is processed in various ways by the processor.

The gate voltage generator 80 generates the gate voltage VG based on the feedback signal SFB output from the signal processing circuit 41 of the output circuit 40. As described below, as the gate voltage VG is applied to the gate electrode 110 of the SPAD device 100, the degree of voltage transfer from a voltage transfer region 501 (see FIG. 4) to a P-type semiconductor region 104 (see FIG. 3) is adjusted. The gate voltage VG may be the same as the anode voltage VA applied to a P-type semiconductor layer 107 (see FIG. 4) through an anode contact 102 (see FIG. 3). The gate voltage VG may be different from the anode voltage VA applied to the P-type semiconductor layer 107. The signal processing circuit 41 and the gate voltage generator 80 constitute a gate voltage controller.

### Operation of SPAD pixel 11

When photons are incident on the SPAD device 100 in a state where the reverse bias voltage VSPAD equal to or greater than the breakdown voltage is applied to the SPAD device 100 through the quench transistor 200, an avalanche current is generated in the SPAD device 100. As the avalanche current flows through the quench transistor 200, a voltage at the node N1 drops. When the voltage at the node N1 falls below a threshold voltage of the PMOS transistor 300P of the inverter 300, the PMOS transistor 300P turns on and the inverter 300 outputs the power supply VHV to the high-level detection signal VD.

Thereafter, when the voltage at the node N1 continues to drop, the voltage applied to the SPAD device 100 falls below the breakdown voltage. Accordingly, the avalanche current does not flow and the voltage at the node N1 increases. When the voltage at the node N1 rises above a threshold voltage of the NMOS transistor 300N of the inverter 300, the NMOS transistor 300N turns on and the inverter 300 outputs a ground voltage to the low-level detection signal VD.

### Stacked Structure of Pixel Array 10

FIG. 3 is a diagram illustrating a stacked structure of the image sensor 1.

The SPAD pixels 11 are arranged in an array to form the pixel array 10. The SPAD devices 100 form a pixel array 70 by arranging the SPAD pixels 11 in an array. The image sensor 1 has a structure in which the pixel chip 500 and the logic chip 600 are stacked. The pixel chip 500 includes a semiconductor chip in which the SPAD devices 100 are formed in an array. The logic chip 600 includes a semiconductor chip in which the quench transistor 200, the inverter 300, and the gate voltage generator 80 are formed at positions corresponding to each SPAD device 100. The logic chip 600 may further include the control circuit 20, the driving circuit 30, and the output circuit 40. The logic chip 600 may be provided with the above-described buffer for impedance conversion of the detection signal VD.

The pixel chip 500 may be bonded to the logic chip 600 by an interelectronic force, for example, by flattening and bringing the respective bonding surfaces thereof into contact with each other. Specifically, the pixel chip 500 may be bonded to the logic chip 600 by metal bonding of metal pads (not shown) formed on the respective surfaces (bonding surfaces) thereof.

### Structure of SPAD device 100

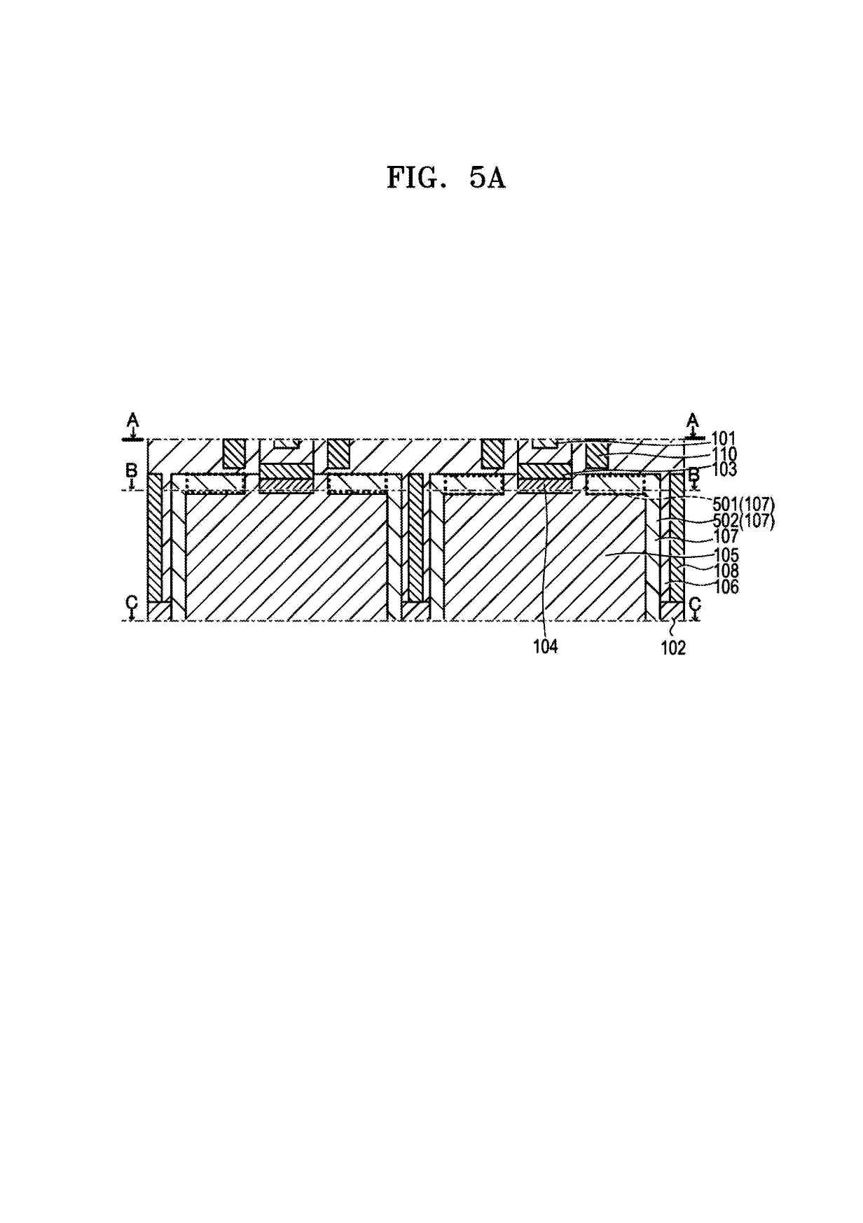

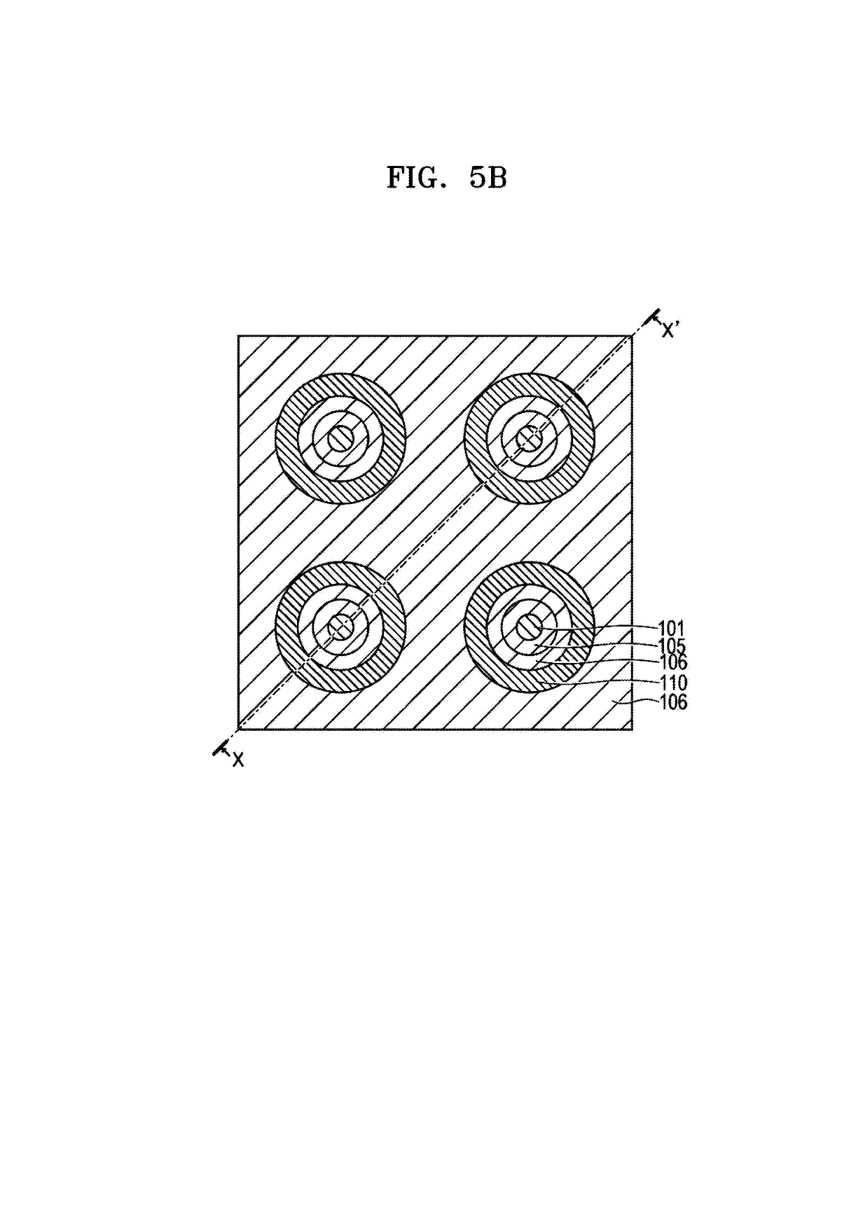

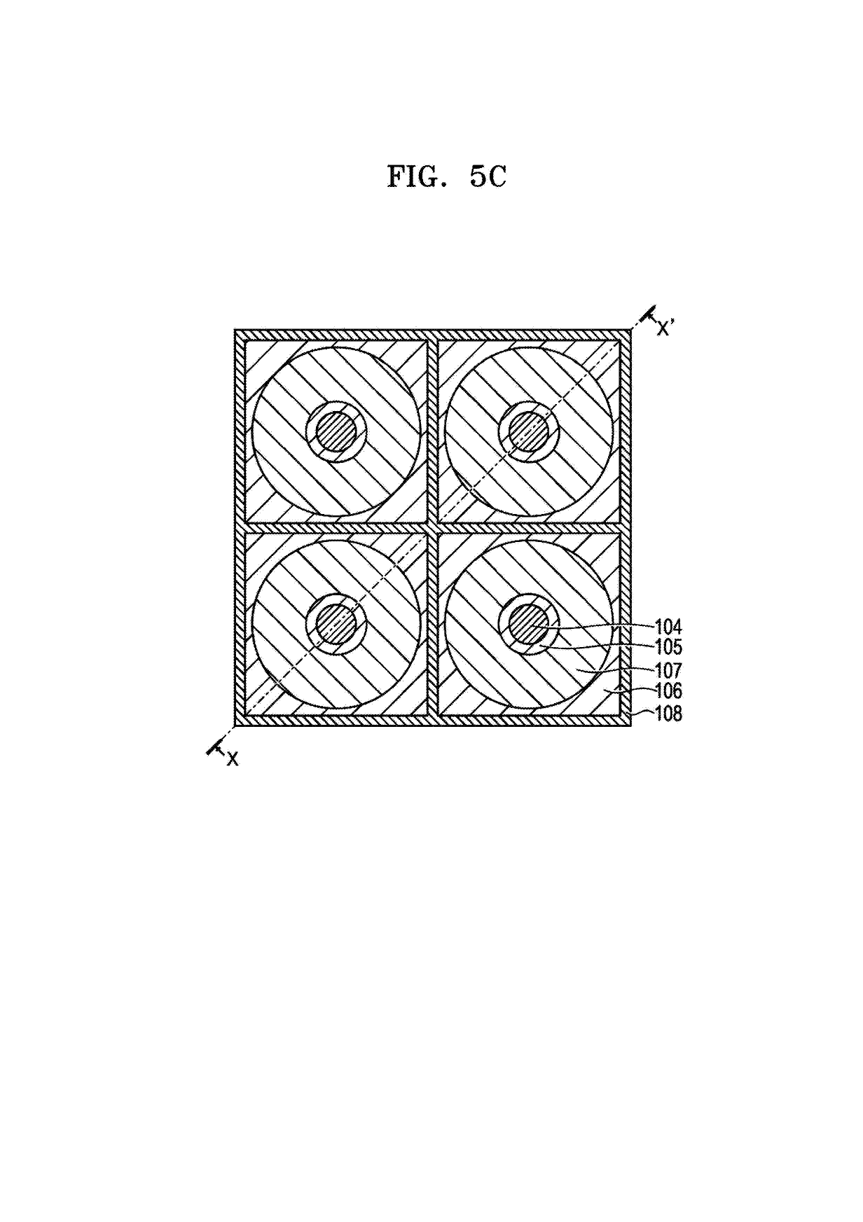

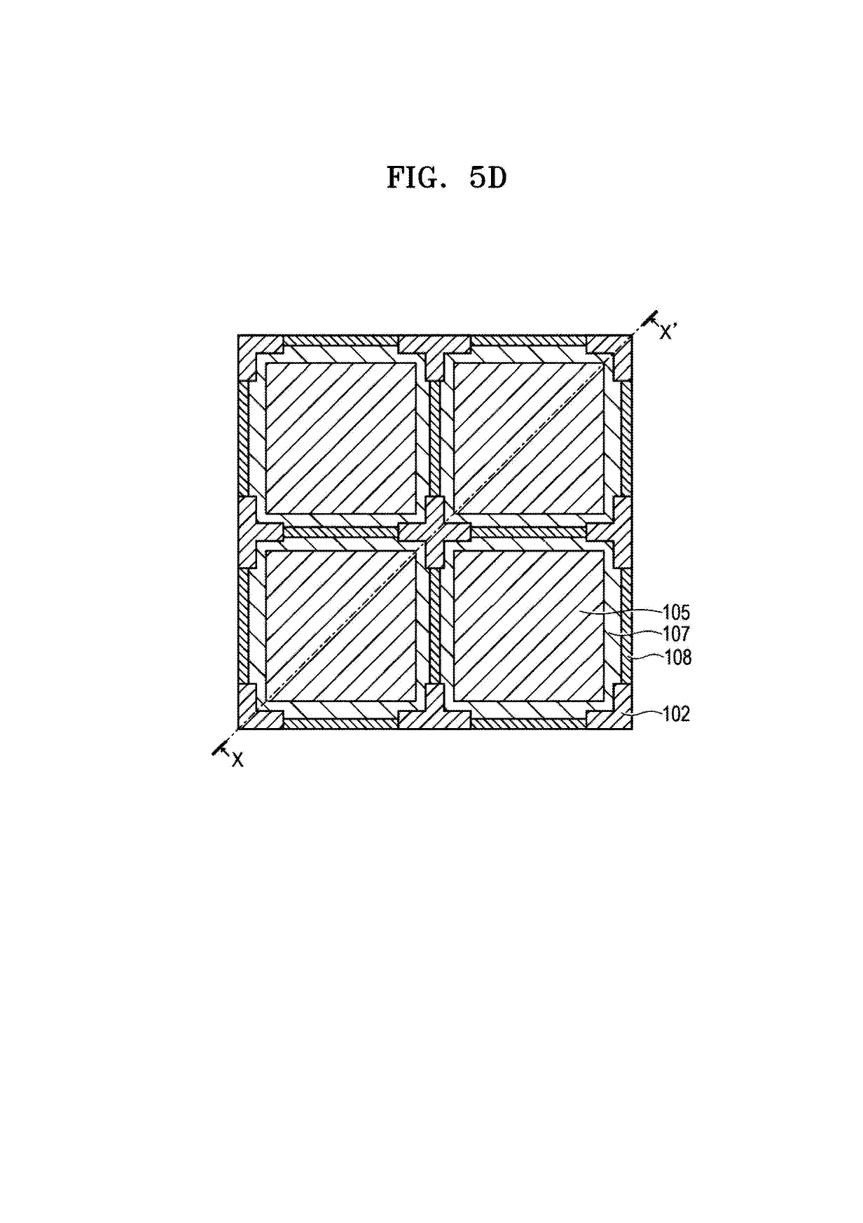

FIG. 4 is a cross-sectional view of a single SPAD device 100. FIGS. 5A to 5D are cross-sectional or plan views of multiple adjacent SPAD devices 100. FIG. 5A is a cross-sectional view taken along line X-X′ in FIG. 5B. FIG. 5B is a plan view of the semiconductor substrate 510, corresponding to a cross-section taken along plane A in FIG. 5A, as viewed from above (the front surface). FIG. 5C is a plan view of the semiconductor substrate 510, corresponding to a cross-section taken along plane B in FIG. 5A, as viewed from above. FIG. 5D is a plan view of the semiconductor substrate 510, corresponding to a cross-section taken along plane C in FIG. 5A, as viewed from above.

In FIG. 4, a surface on which light is incident, which is indicated by a straight arrow, is the light incident surface.

The SPAD device 100 is formed on the semiconductor substrate 510 of the pixel chip 500. The semiconductor substrate 510 includes, for example, a substrate of silicon. Hereinafter, for simplicity of description, a case where the semiconductor substrate 510 is the substrate of silicon is described as an example.

Each SPAD device 100 includes a trench 109 for separating the same from other SPAD devices 100. The trenches 109 of the SPAD devices 100 formed on the semiconductor substrate 510 are connected to each other to form a lattice pattern when viewed in plan from the light incident surface.

The photoelectric conversion region 105 photoelectrically converts incident light to generate an electron-hole pair (hereinafter, also referred to as “charge”). The photoelectric conversion region 105 is composed of a region doped with an impurity at a relatively low concentration. Hereinafter, for simplicity of description, a case where the photoelectric conversion region 105 is a semiconductor layer doped with an N-type impurity at a relatively low concentration is described as an example. For example, phosphorus (P) or arsenic (As) is used as the N-type impurity. The photoelectric conversion region 105 may include an intrinsic semiconductor that is not doped with impurities.

The P-type semiconductor layer 107 is a layer containing a P-type impurity and is formed around a cathode contact 101. For example, boron (B) is used as the P-type impurity. The P-type semiconductor layer 107 includes the voltage transfer region 501 indicated by a portion surrounded by a dotted line in FIG. 4. A region other than the voltage transfer region 501 of the P-type semiconductor layer 107 constitutes a charge induction region 502 for inducing the photoelectrically converted charge to an electron multiplication region. The voltage transfer region 501 may be arranged around the cathode contact 101 and may transfer the anode voltage VA applied to the anode contact 102 to the P-type semiconductor region 104. The charge induction region 502 may be formed on a sidewall of the trench 109 and may be adjacent to a first insulating film 106 formed on the sidewall of the transistor 109. The charge induction region 502 may also be formed on the back surface of the substrate 510.

The anode contact 102 may be formed on the back surface of the semiconductor substrate 510. The anode contact 102 is in contact with the charge induction region 502. The anode contact 102 includes, e.g., polysilicon. The anode contact 102 may be formed as a region including the P-type impurity at a greater concentration than the P-type semiconductor region 104. For example, the anode contact 102 forms an ohmic contact with an anode wiring (not shown) which is a wiring pattern of a metal layer formed in a wiring layer 520. As the anode contact 102 is formed in a region including an intersection of the lattice-shaped trenches 109, the anode contact 102 may be shared between the SPAD devices 100.

The charge induction region 502 forms an electric field for leading the charge generated in the photoelectric conversion region 105 to the electron multiplication region by applying the reverse bias voltage VSPAD between the anode contact 102 and the cathode contact 101 of the SPAD device 100. The electron multiplication region is formed, for example, as a PN junction of an N-type semiconductor region 103 and a P-type semiconductor region 104. The P-type semiconductor region 104 constitutes a first region. The N-type semiconductor region 103 constitutes a second region.

The anode contact 102 and the charge induction region 502 constitute an anode electrode. The cathode contact 101 constitutes a cathode electrode. The periphery of the cathode electrode refers at least to a periphery thereof when the SPAD device 100, which is a photoelectric conversion device, is viewed from the top (plan view).

The P-type semiconductor region 104 includes a region including the P-type impurity at a relatively high concentration. For example, B is used as the P-type impurity. The N-type semiconductor region 103 includes a region including the N-type impurity at a relatively high concentration. For example, P or As is used as the N-type impurity. The P-type semiconductor region 104 and the N-type semiconductor region 103 are in contact with each other to form the PN junction and function as the electron multiplication region that accelerates the charge flowing into the P-type semiconductor region 104 to generate the avalanche current.

The cathode contact 101 is a region containing the N-type impurity at a greater concentration than the N-type semiconductor region 103 and is in contact with the photoelectric conversion region 105. The cathode contact 101 may form an ohmic contact with the cathode wiring 111, which is a wiring pattern of the metal layer formed in the wiring layer 520.

The gate electrode 110 is arranged around the cathode contact 101 and faces the voltage transfer region 501 with the first insulating film 106 positioned therebetween. The gate electrode 110 may form an ohmic contact with the gate wiring 112, which is a wiring pattern of the metal layer formed in the wiring layer 520. The degree of transfer of the anode voltage VA from the voltage transfer region 501 to the P-type semiconductor region 104 may be adjusted by the gate voltage VG applied from the gate wiring 112 to the gate electrode 110.

As shown in FIG. 4, the gate electrode 110 may extend long in the thickness direction of the substrate 510 in a cross-sectional view. For example, the thickness direction may be along a direction perpendicular to a top surface of the substrate 510.

As shown in FIG. 5B, the gate electrode 110 may be formed in an annular shape surrounding the cathode contact 101 when viewed in a direction perpendicular to the front surface of the substrate 510.

The gate electrode 110 may include one or more materials including polysilicon and/or metal.

The gate voltage VG applied to the gate electrode 110 may be the same as the anode voltage VA applied to the anode contact 102. The gate voltage VG may be different from the anode voltage VA. The gate voltage VG may include, for example, any value of about -20 V to about -10 V. The gate voltage VG may be set based on a potential distribution in the substrate 510 of the SPAD device 100 when the gate voltage VG is not applied to the gate electrode 110, as described below.

An isolation conductive layer 108 may include metal or polysilicon. The isolation conductive layer 108 includes, for example, tungsten (W). The isolation conductive layer 108 is arranged around each SPAD pixel 11, and is formed in a lattice pattern in the pixel array 10. The isolation conductive layer 108 constitutes an isolation portion.

The first insulating film 106 covering the isolation conductive layer 108 is formed inside the trench 109. The isolation conductive layer 108 and the first insulating film 106 are formed inside the trench 109 to form a deep trench isolation (DTI). The first insulating film 106 constitutes an insulating film.

The first insulating film 106 may be in contact with the voltage transfer region 501. The first insulating film 106 may be in contact with the isolation conductive layer 108.

The first insulating film 106 may have the same length in the thickness direction of the semiconductor substrate 510 on the inner side and the outer side of the gate electrode 110 surrounding the cathode contact 101.

The first insulating film 106 includes, for example, a silicon oxide film.

An anti-reflection film (not shown) for preventing reflection of incident light may be formed on the back surface (light incident surface) of the semiconductor substrate 510.

A color filter (not shown) and an on-chip lens (not shown) corresponding to each SPAD device 100 may be formed on the anti-reflection film. The color filter may correspond to each SPAD device 100 and may include any one of a color filter selectively transmitting light of a red (R) wavelength component, a color filter selectively transmitting light of a green (G) wavelength component, and a color filter selectively transmitting light of a blue (B) wavelength component. Each of the color filters may be formed in a Bayer array.

The wiring layer 520 is formed on the front surface of the semiconductor substrate 510. The wiring layer 520 is constituted by a second insulating film (not shown) and a plurality of wirings 700 formed therein. The plurality of wirings 700 may be stacked with the second insulating film arranged therebetween. In that case, adjacent wirings 700 of the same node, with the second insulating film arranged therebetween, are electrically connected to each other through a via formed in the second insulating film. The wiring 700 may include an anode wiring (not shown) for supplying the anode voltage VA to the SPAD device 100 and a cathode wiring 111 for supplying the cathode voltage VC to the SPAD device 100. The wiring 700 may further include a gate wiring 112. The anode wiring 112 is connected to the anode contact 102. The cathode wiring 111 is connected to the cathode contact 101. The gate wiring 112 is connected to the gate electrode 110. The wiring 700 includes a first connection pad (not shown). The first connection pad may be exposed at a surface (a lower surface in FIG. 4) of the wiring layer 520.

The first connection pad may be bonded to a second connection pad (not shown) exposed at a surface of the logic chip 600 by metal bonding. Thus, the pixel chip 500 may be bonded to the logic chip 600.

The logic chip 600 may include a substrate and a wiring layer. In this case, a device constituting a logic circuit, including transistors constituting the quench transistor 200 and the inverter 300, and the gate voltage generator 80, is formed on the substrate. In addition, a wiring for configuring the logic circuit, including a wiring connecting the quench transistor 200 to the inverter 300 or a wiring including the second connection pad, is formed in the wiring layer.

### Operation Resulting From Application of Gate Voltage VG to Gate Electrode 110

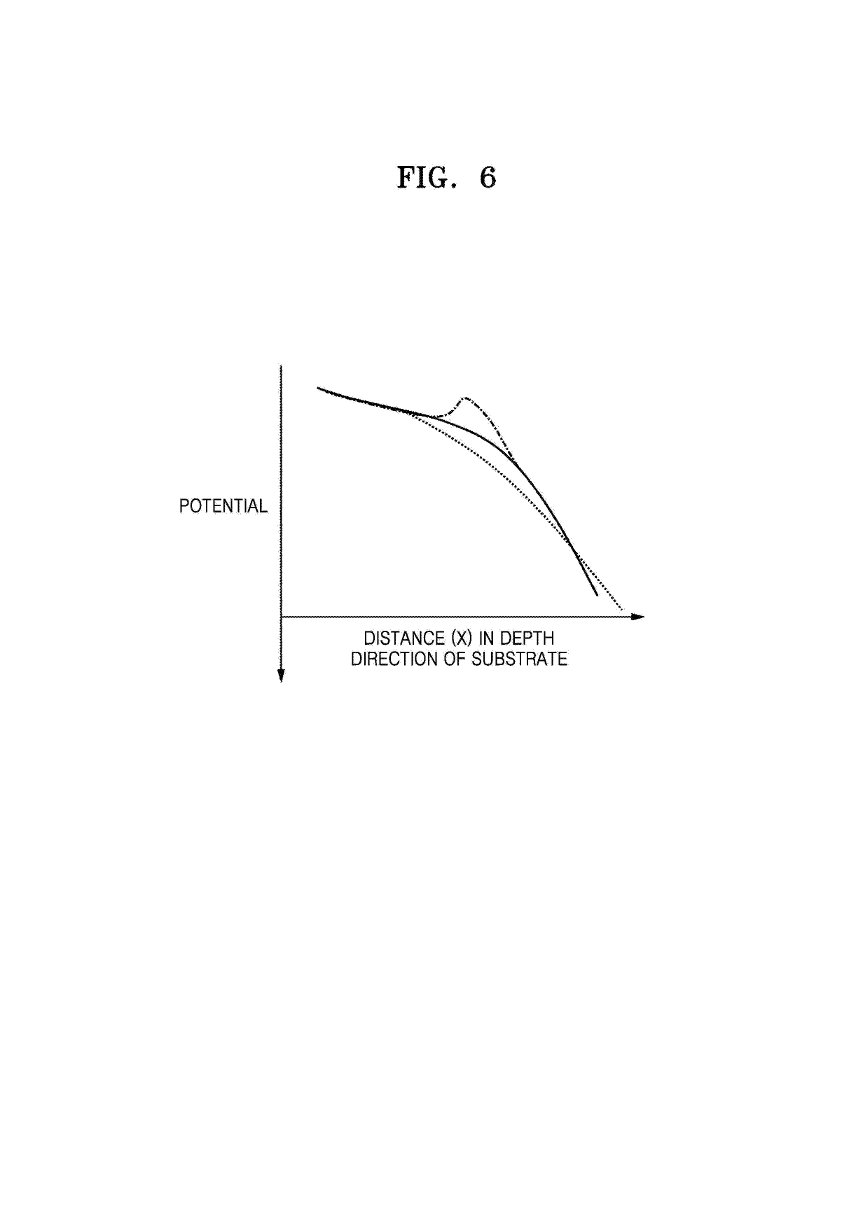

FIG. 6 is a graph of potential with respect to distance X in a depth direction of the substrate 510 along a dashed-dotted line arrow in FIG. 4.

In the graph of FIG. 6, a solid line shows an ideal potential profile in which the multiplication probability increases. The sensitivity of the SPAD device 100 is given by the product of quantum efficiency and multiplication probability. A dashed-dotted line in the graph shows a potential profile in which a barrier is generated. A dotted line in the graph shows a potential profile in which the electric field in the electron multiplication region is weak. The potential profile of the SPAD device 100, among the above potential profiles, is taken depending on the design factors, such as arrangement, shape, and dimensions of the respective layers constituting the SPAD device 100, but is also relatively significantly affected by manufacturing variations.

In the SPAD device 100 having the potential profile in which the barrier is generated, as shown by the dashed-dotted line in the graph, the multiplication probability becomes relatively low because the electrons generated in the photoelectric conversion region 105 are hindered from reaching the electron multiplication region. In the SPAD device 100 having the potential profile in which the electric field is weak, as shown by the dotted line in the graph, the multiplication probability due to avalanche breakdown becomes low because the electric field in the electron multiplication region is small. To increase the multiplication probability, it is necessary that the potential profile of the SPAD device 100, as shown by the solid line in the graph, be formed into a potential profile in which the barrier is not generated and the electric field is large.

In the case of the SPAD device 100 having a potential profile, when the gate voltage VG is not applied to the gate electrode 110 that corresponds to the potential profile shown by the dotted line in the graph of FIG. 6, the gate voltage VG having a relatively low potential (a potential slightly greater than the anode potential) is applied to the gate electrode 110. Accordingly, as the degree of transfer of the anode voltage VA from the voltage transfer region 501 to the P-type semiconductor region 104 increases, the potential profile may be raised to approximate the ideal potential profile shown by the solid line. In the case of the SPAD device 100 having a potential profile, when the gate voltage VG is not applied to the gate electrode 110 that corresponds to the potential profile shown by the dashed-dotted line in the graph of FIG. 6, the gate voltage VG having a relatively high potential (a potential relatively greater than the anode potential) is applied to the gate electrode 110. Accordingly, as the degree of transfer of the anode voltage VA from the voltage transfer region 501 to the P-type semiconductor region 104 decreases, the potential profile may be lowered to approximate the ideal potential profile shown by the solid line.

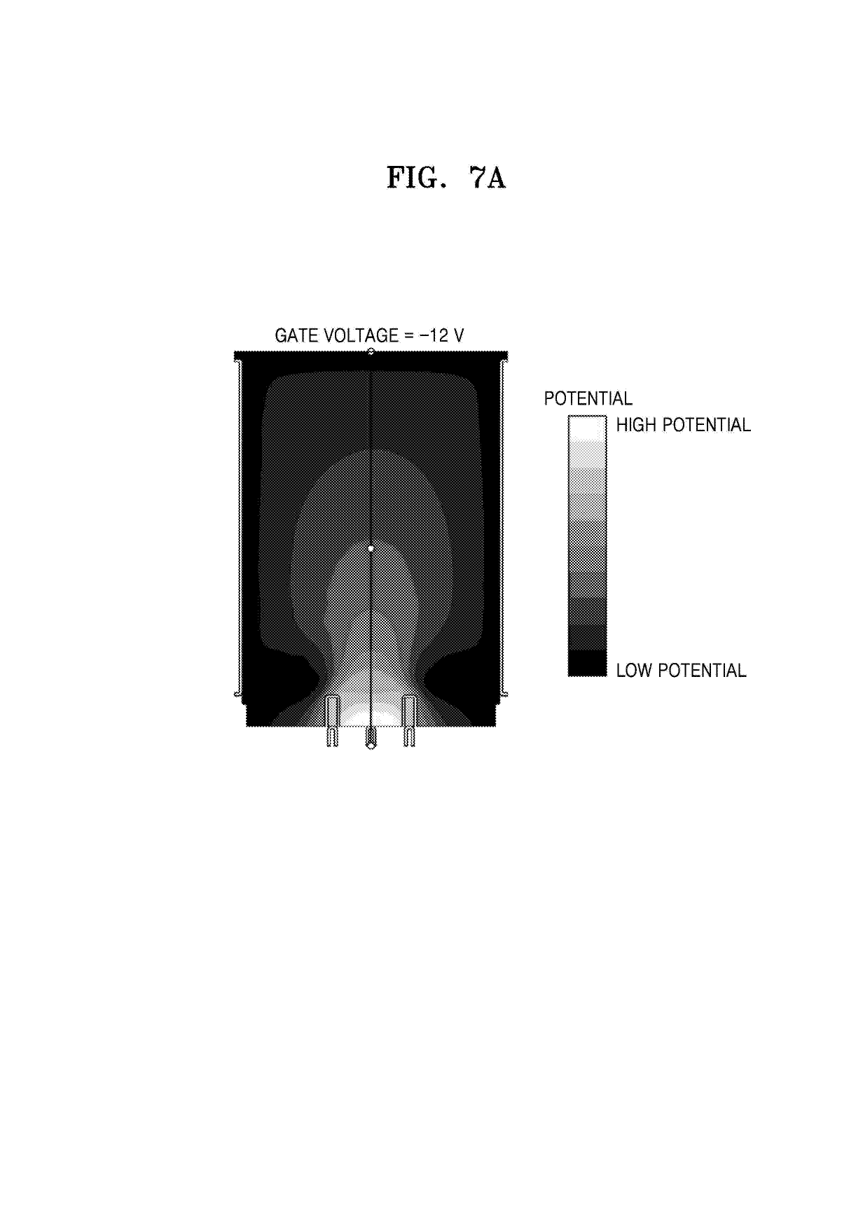

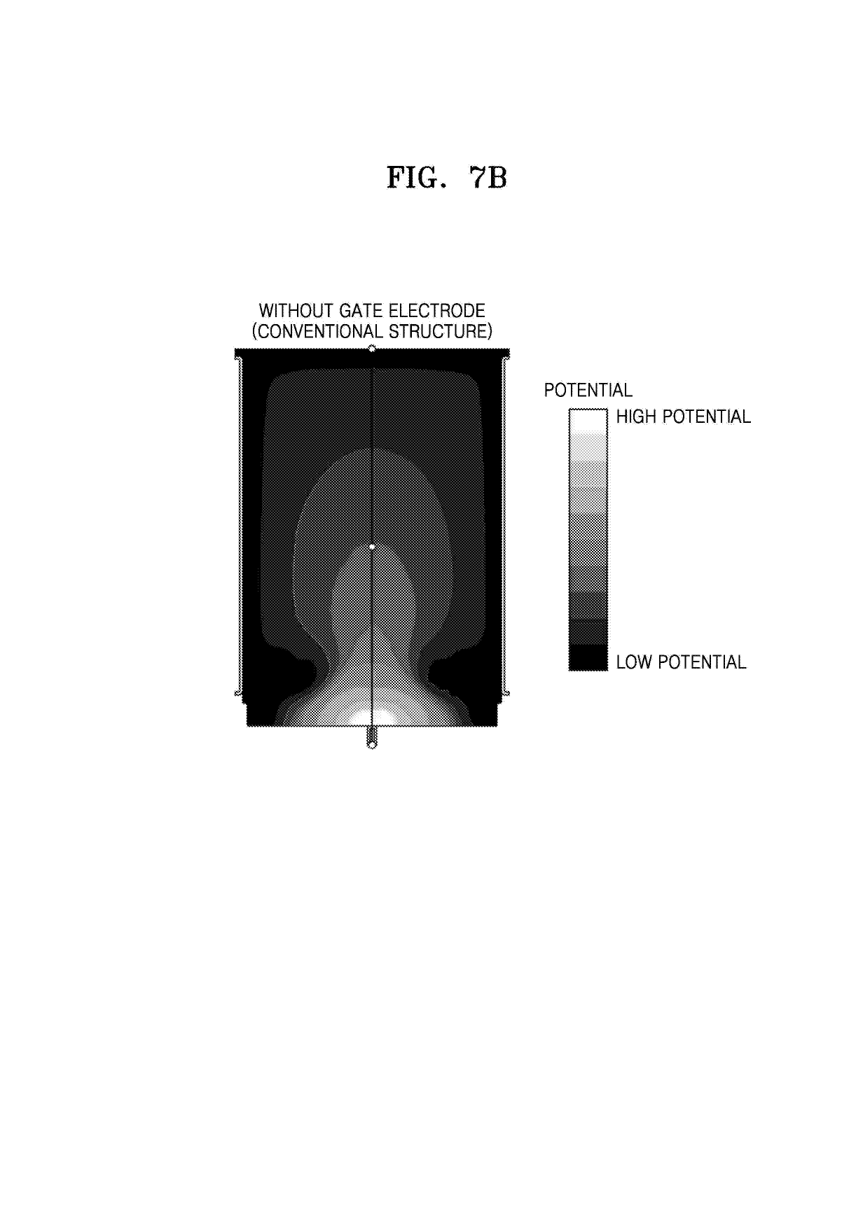

FIG. 7A is a diagram illustrating a potential distribution at each position in the substrate 510 when the gate voltage VG is applied to the gate electrode 110. The gate voltage VG is -12 V. FIG. 7B is a diagram illustrating a potential distribution at each position in the substrate 510 having a conventional structure without the gate electrode 110. In FIGS. 7A and 7B, the anode voltage is -21 V and the cathode voltage is 1 V. In these drawings, a higher potential is represented by a color of a higher brightness tone. In addition, the position along the center straight line in each drawing corresponds to the distance X in the depth direction of the substrate 510 which is the horizontal axis of the graph of FIG. 6.

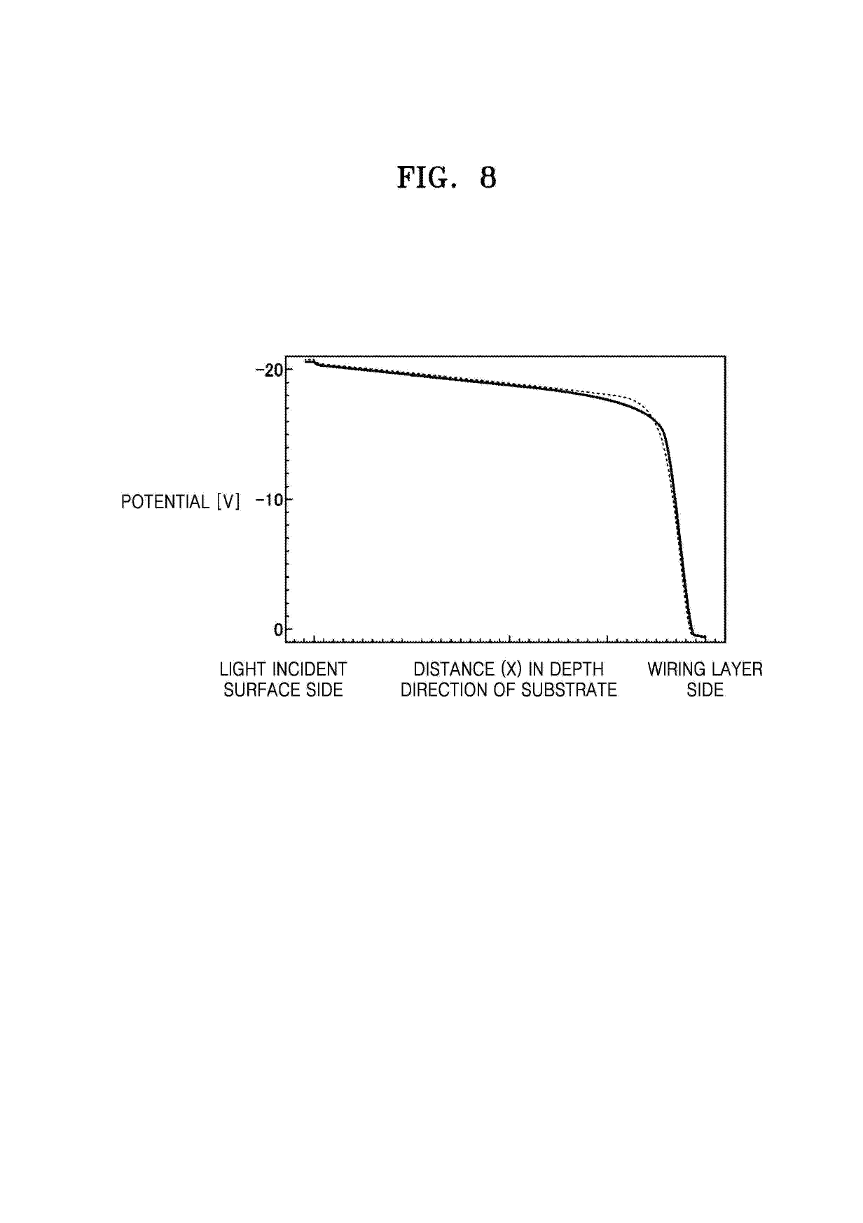

FIG. 8 is a graph of potential with respect to distance X in the depth direction of the substrate 510, along the dashed-dotted line arrow in FIG. 4, showing a difference in the potential depending on whether the gate voltage VG is applied to the gate electrode 110. The dotted line in the graph indicates that the gate voltage VG is not applied to the gate electrode 110, and the solid line in the graph indicates that the gate voltage VG is applied to the gate electrode 110. The electron multiplication region corresponds to the position at the distance X where the potential is largely displaced.

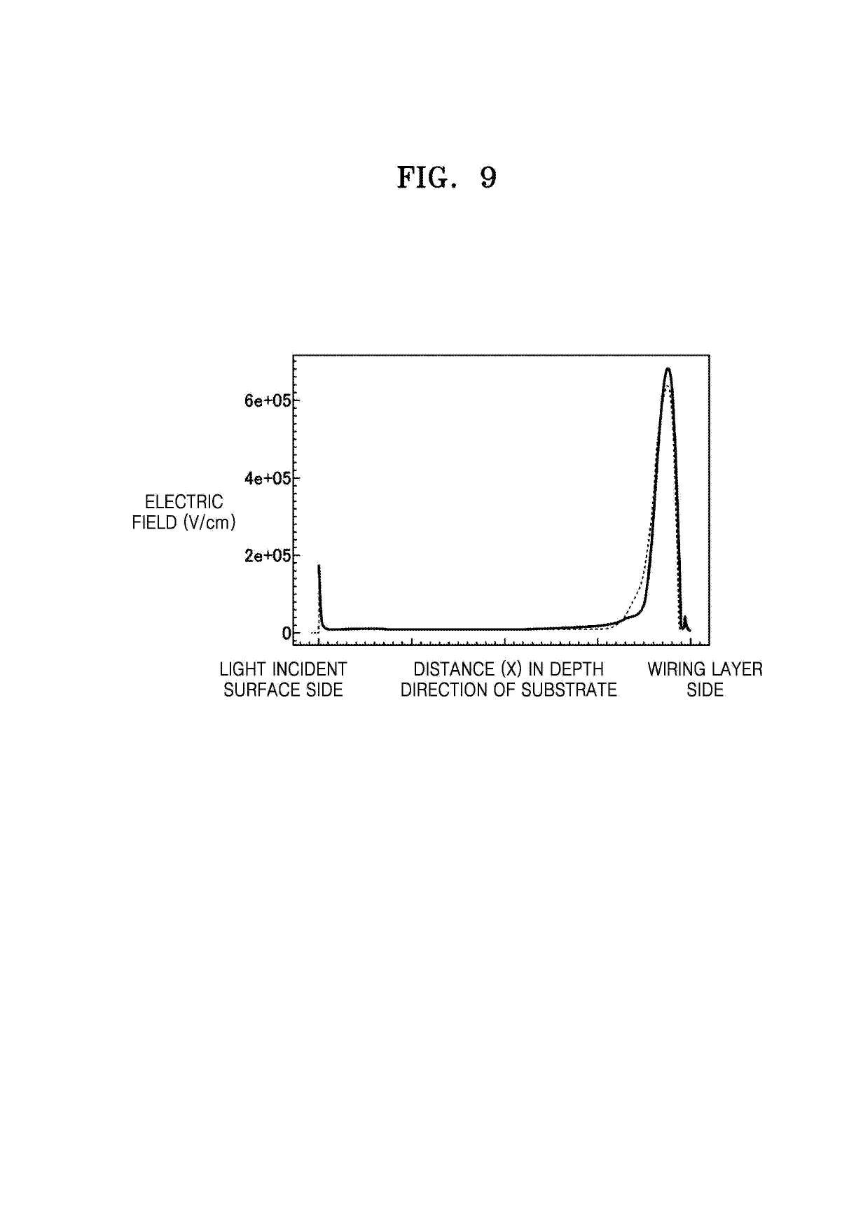

FIG. 9 is a graph of electric field with respect to distance X in the depth direction of the substrate 510, along the dashed-dotted line arrow in FIG. 4, showing a difference in the electric field depending on whether the gate voltage VG is applied to the gate electrode 110. The dotted line in the graph indicates that the gate voltage VG is not applied to the gate electrode 110 and the solid line in the graph indicates that the gate voltage VG is applied to the gate electrode 110

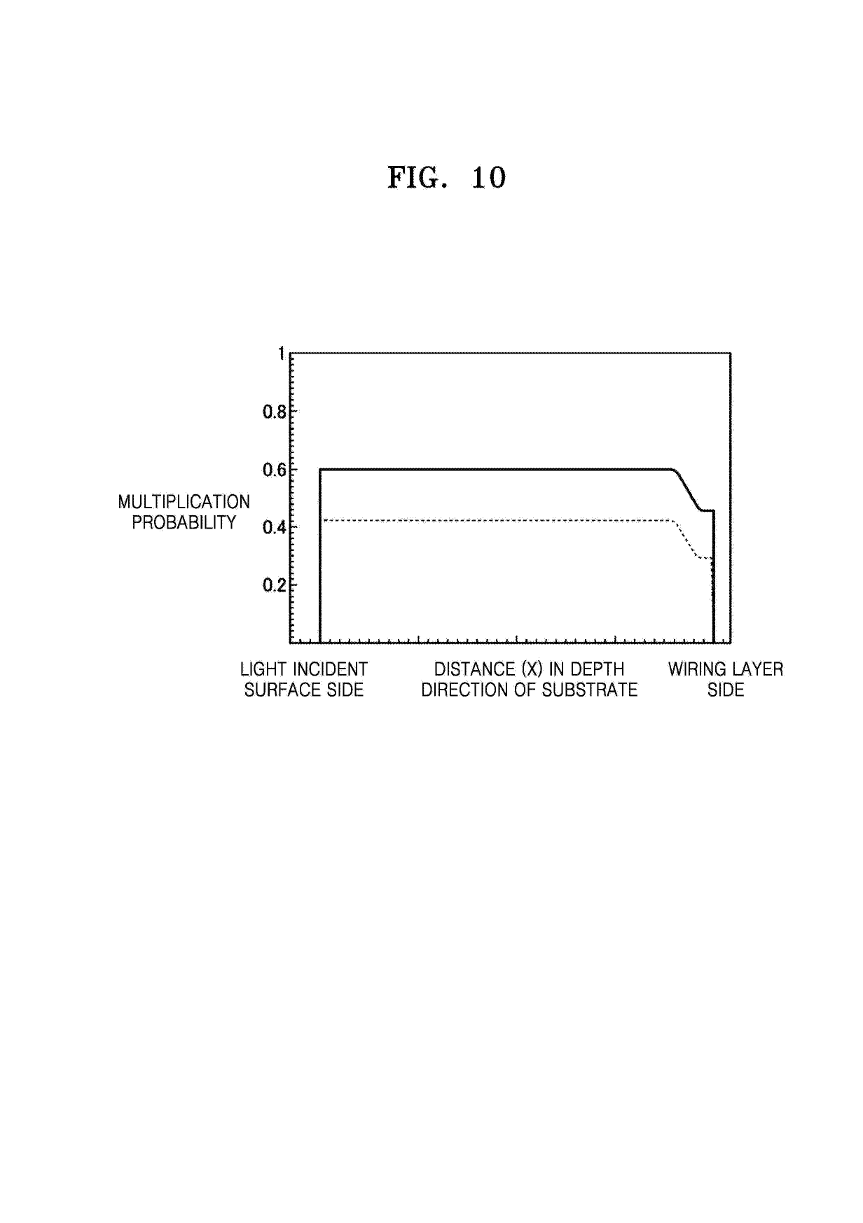

FIG. 10 is a graph of multiplication probability with respect to distance X in the depth direction of the substrate 510, along the dashed-dotted line arrow in FIG. 4, showing a difference in the multiplication probability depending on whether the gate voltage VG is applied to the gate electrode 110. The dotted line in the graph indicates that the gate voltage is not applied to the gate electrode 110, and the solid line in the graph indicates that the gate voltage is applied to the gate electrode 110.

With reference to FIG. 7A, FIG. 7B, and FIG. 8 to FIG. 10, described is an operation in which the multiplication probability is improved without changing the reverse bias voltage VSPAD applied to the SPAD device 100 by applying the gate voltage VG to the gate electrode 110.

As can be seen from the comparison between FIGS. 7A and 7B, by applying the gate voltage VG to the gate electrode 110, the degree of voltage transfer from the voltage transfer region 501 facing the gate electrode 110 with the first insulating film 106 arranged therebetween to the P-type semiconductor region 104 of the electron multiplication region is adjusted, thereby modulating the potential in the vicinity of the electron multiplication region. Accordingly, as shown in FIG. 8, the potential gradient may be made steeper by applying the gate voltage VG to the gate electrode 110. For example, as shown in FIG. 9, the electric field that is the spatial derivative of the potential may be increased by applying the gate voltage VG to the gate electrode 110. As shown in FIG. 10, the multiplication probability may be improved by applying the gate voltage VG to the gate electrode 110 because the multiplication probability depends on the electric field.

The operation of suppressing the deterioration of dark count rate (DCR) by applying the gate voltage VG to the gate electrode 110 is described below.

In the case where the gate electrode 110 is not provided, it is generally necessary to increase the reverse bias voltage VSPAD to improve the multiplication probability. However, when the reverse bias voltage VSPAD is increased, the multiplication probability may be unintentionally increased not only inside the electron multiplication region but also outside the multiplication region, thereby deteriorating the DCR. Furthermore, when the reverse bias voltage VSPAD is increased, a region where the multiplication probability increases tends to expand toward the front surface of the substrate 510 facing the wiring layer 520. Since a dark current is particularly likely to be generated at a silicon interface on the front surface of the substrate 510, the dark current multiplies and relatively significantly contributes to the deterioration of the DCR.

The gate electrode 110 for adjusting the degree of voltage transfer from the voltage transfer region 501 to the P-type semiconductor region 104 in the electron multiplication region may be provided, and the gate voltage VG may be applied to the gate electrode 110 to modulate the potential in the vicinity of the electron multiplication region. Accordingly, by preventing the region where the multiplication probability increases from expanding toward the front surface of the substrate 510 facing the wiring layer 520, the deterioration of the DCR may be effectively suppressed.

The DCR characteristics and sensitivity of the SPAD device 100 may vary for each SPAD device 100 due to manufacturing variations. However, by optimizing the gate voltage VG applied to the gate electrode 110 for each SPAD device 100, variations in the DCR characteristics and sensitivity of the SPAD device 100 may be reduced. For example, the gate voltage VG to be applied to the gate electrode 110 is adjusted for each SPAD device 100 so that the DCR characteristics and sensitivity of each SPAD device 100 satisfy certain specifications, thereby optimizing the gate voltage VG to be applied to each SPAD device 100.

### Method of Manufacturing Image Sensor 1

A method of manufacturing the image sensor 1 is described.

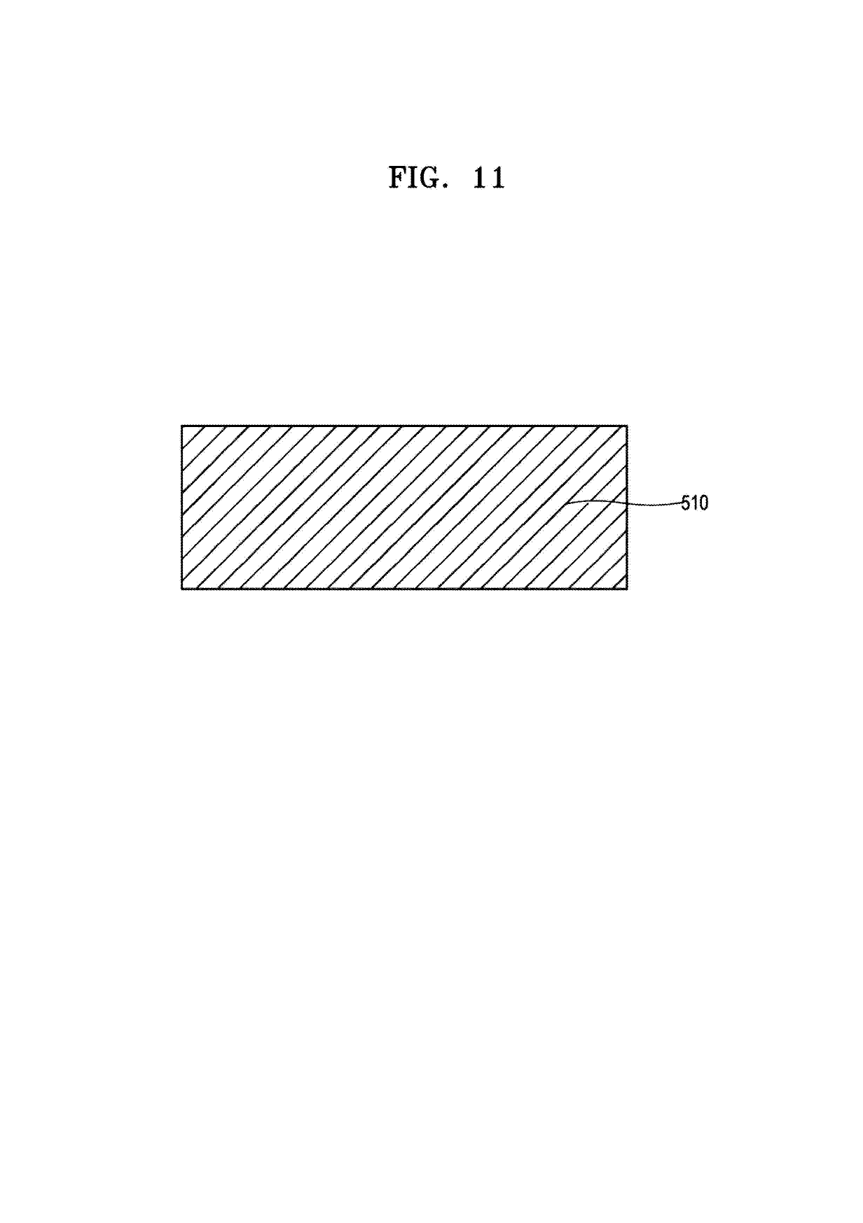

FIGS. 11 to 19 are cross-sectional views illustrating the method of manufacturing the image sensor 1. FIGS. 11 to 19 correspond to the method of manufacturing the image sensor 1 including the SPAD device 100 shown in FIGS. 5A to 5C.

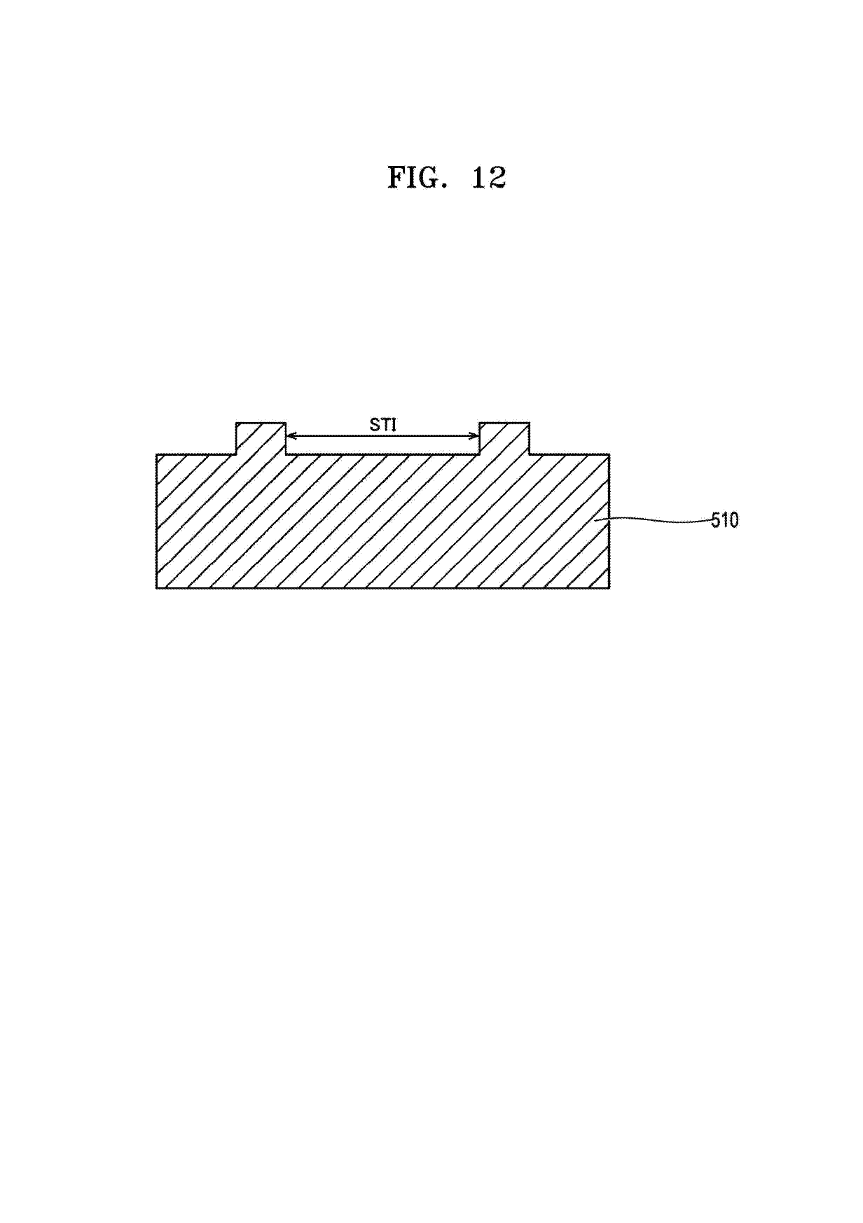

As shown in FIGS. 11 and 12, a pattern of shallow trench isolation (STI) is formed by etching the front surface of the semiconductor substrate 510 using a photolithography technique.

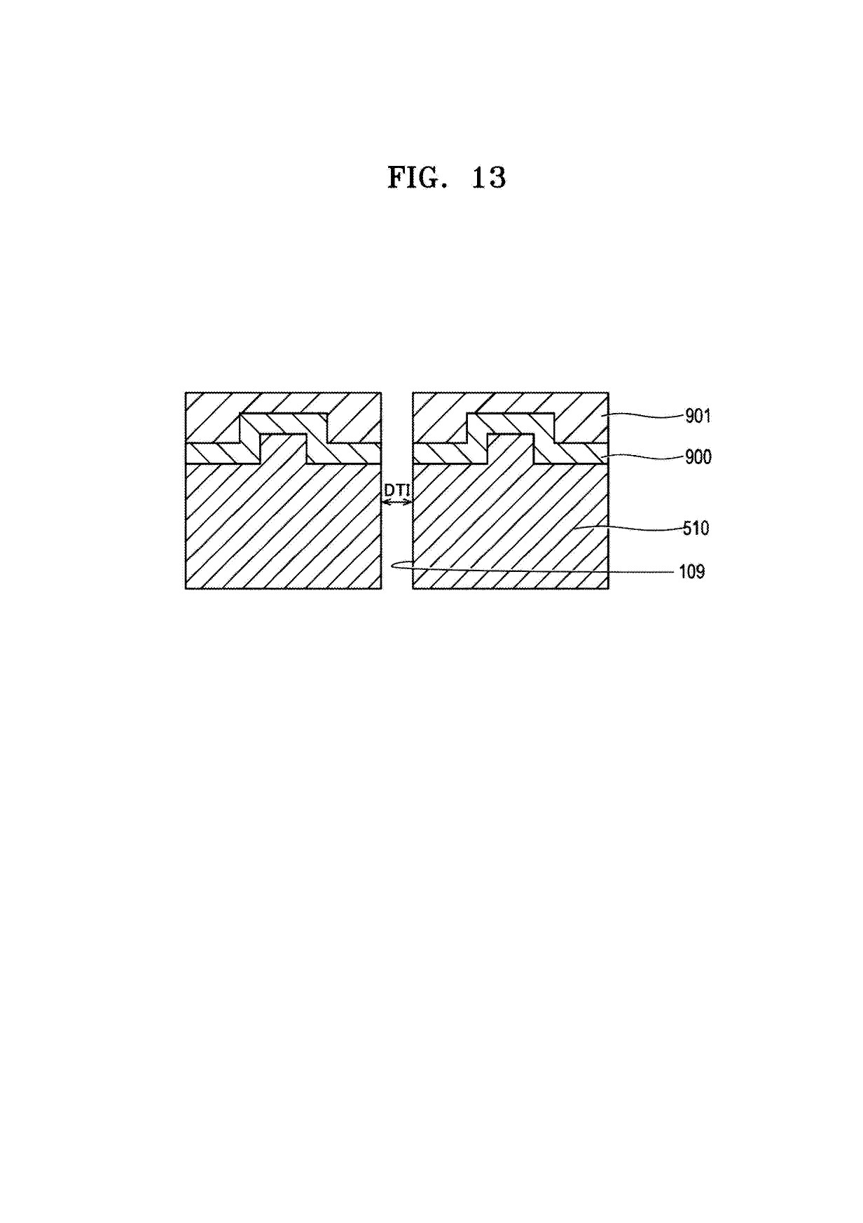

Next, as shown in FIG. 13, a silicon oxide film 900 and a silicon nitride film 901, which are used as hard mask materials for forming the trench 109 of the DTI, are deposited on the pattern of the STI and planarized by chemical mechanical polishing (CMP). Then, the silicon oxide film 900 and the silicon nitride film 901 are etched using a mask in which an opening corresponding to the position of the trench 109 is formed. Then, by etching the semiconductor substrate 510 using the silicon oxide film 900 and the silicon nitride film 901, in which the opening corresponding to the position of the trench 109 is formed by etching, as masks, the trench 109 is formed.

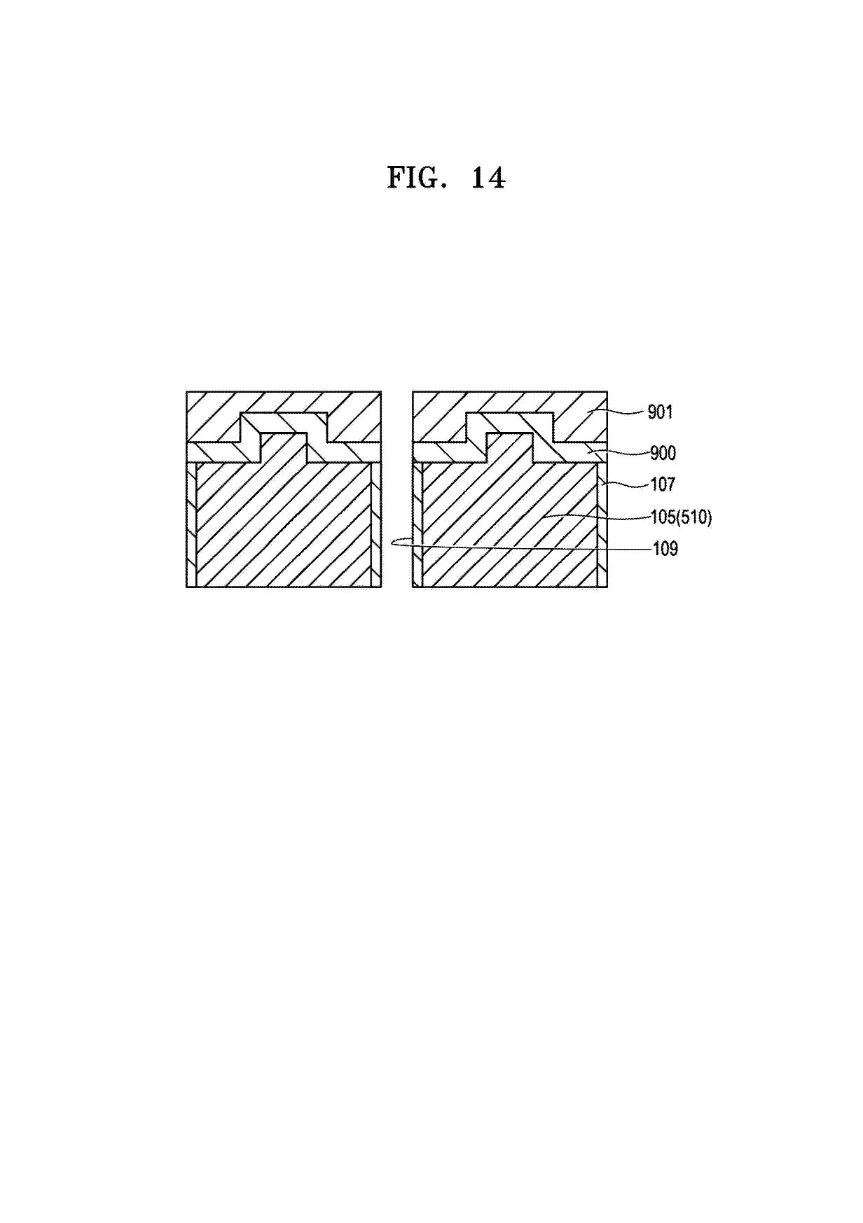

Next, as shown in FIG. 14, as the P-type impurity is implanted into the sidewall of the trench 109 and activated by heat treatment, the P-type semiconductor layer 107 is formed on the sidewall of the trench 109. For example, B is used as the P-type impurity.

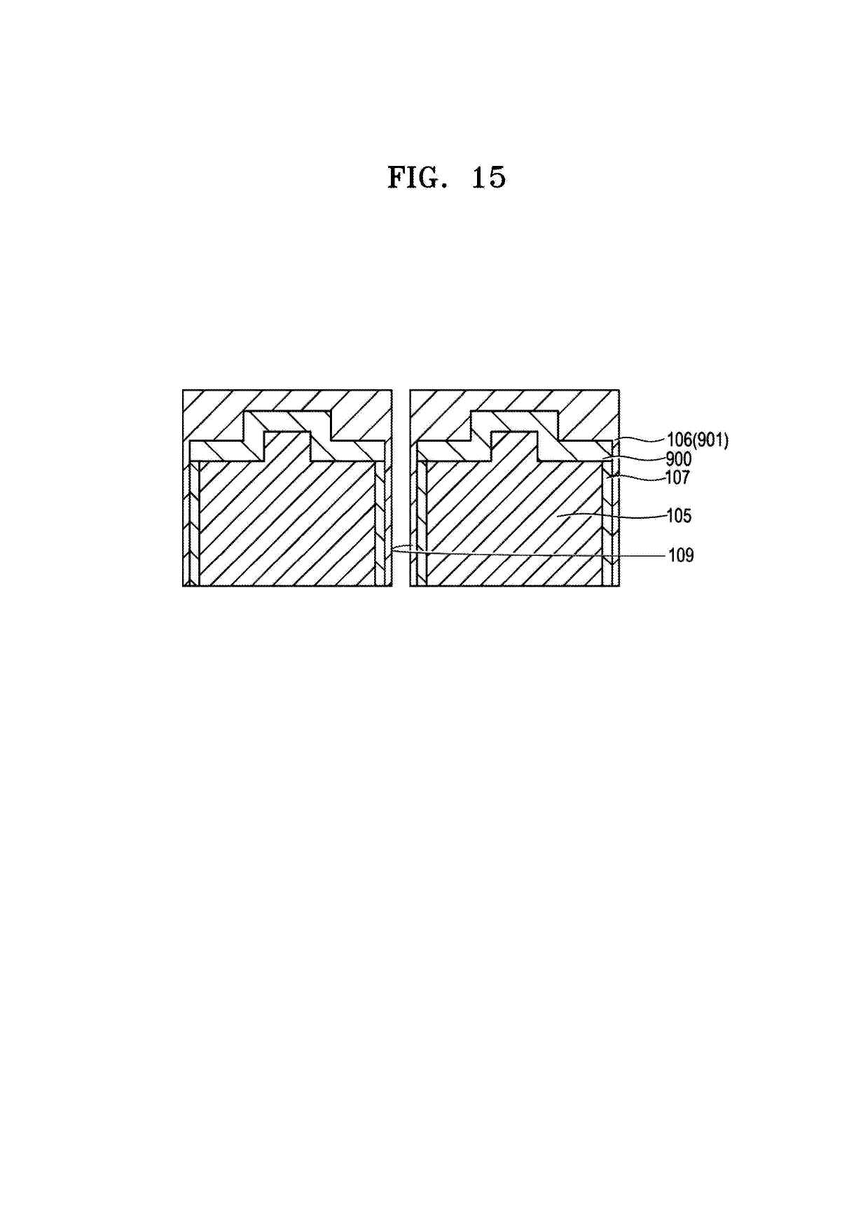

Next, as shown in FIG. 15, the first insulating film 106 is formed on a sidewall inside the trench 109. Accordingly, the first insulating film 106 covering the P-type semiconductor layer 107 is formed on the sidewalls inside the trench 109.

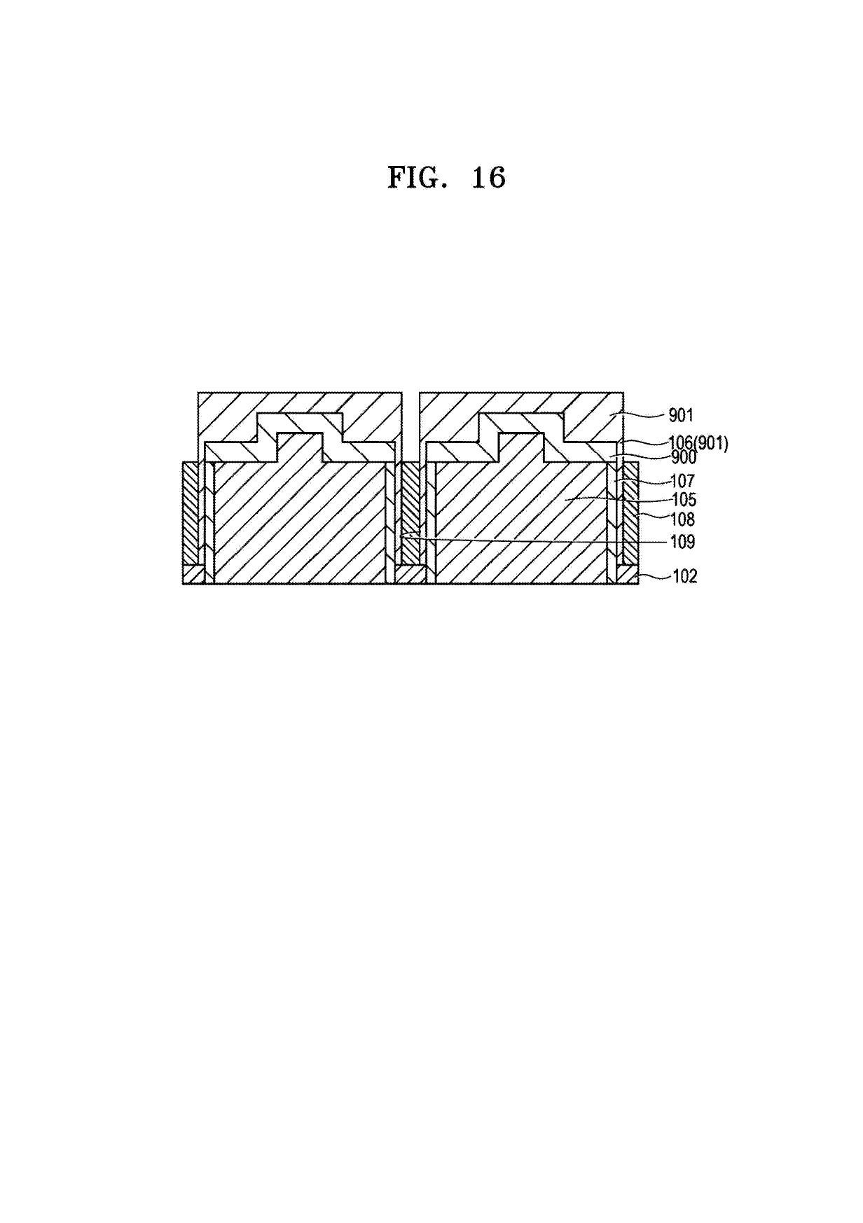

Next, as shown in FIG. 16, a portion of the first insulating film 106 is removed by isotropic etching to expose a portion of the P-type semiconductor layer 107. Then, the anode contact 102 in contact with the exposed P-type semiconductor layer 107 is formed. The anode contact 102 is formed by, for example, depositing polysilicon doped with B, which is the P-type impurity, inside the trench 109 using CVD, and then removing a portion of the polysilicon using etch-back. Then, the isolation conductive layer 108 in contact with the first insulating film 106 and the anode contact 102 is formed in the trench 109. The isolation conductive layer 108 is formed, for example, by depositing polysilicon in the trench 109 using chemical vapor deposition (CVD) and then removing a portion of the polysilicon using etch-back.

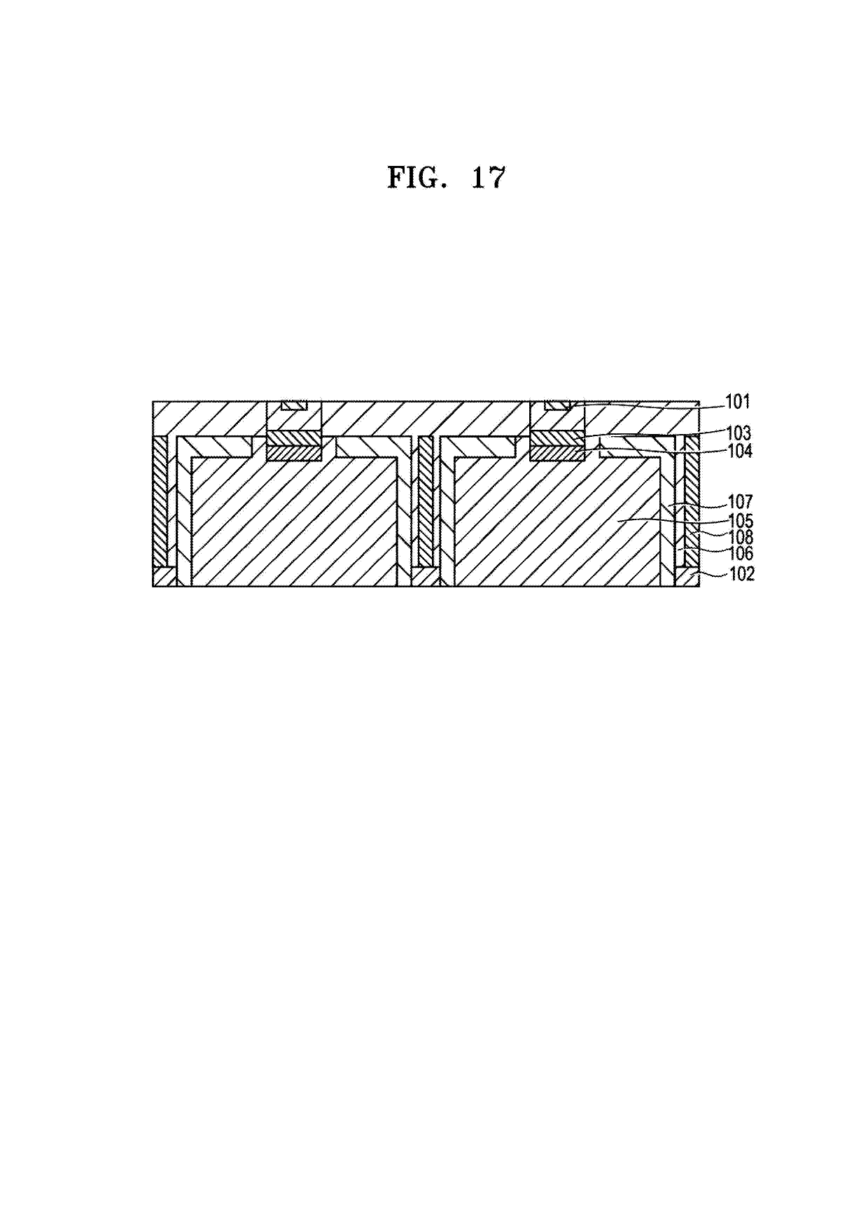

Next, as shown in FIG. 17, by depositing silicon oxide after the above-described pattern of the STI is exposed by removing the silicon oxide film 900 and the silicon nitride film 901, the first insulating film 106 is formed in the trench of the STI. Accordingly, the STI is formed. Thereafter, each impurity is implanted into the portion surrounded by the STI and activated by heat treatment, whereby the P-type semiconductor region 104, the N-type semiconductor region 103, and the cathode contact 101 are formed.

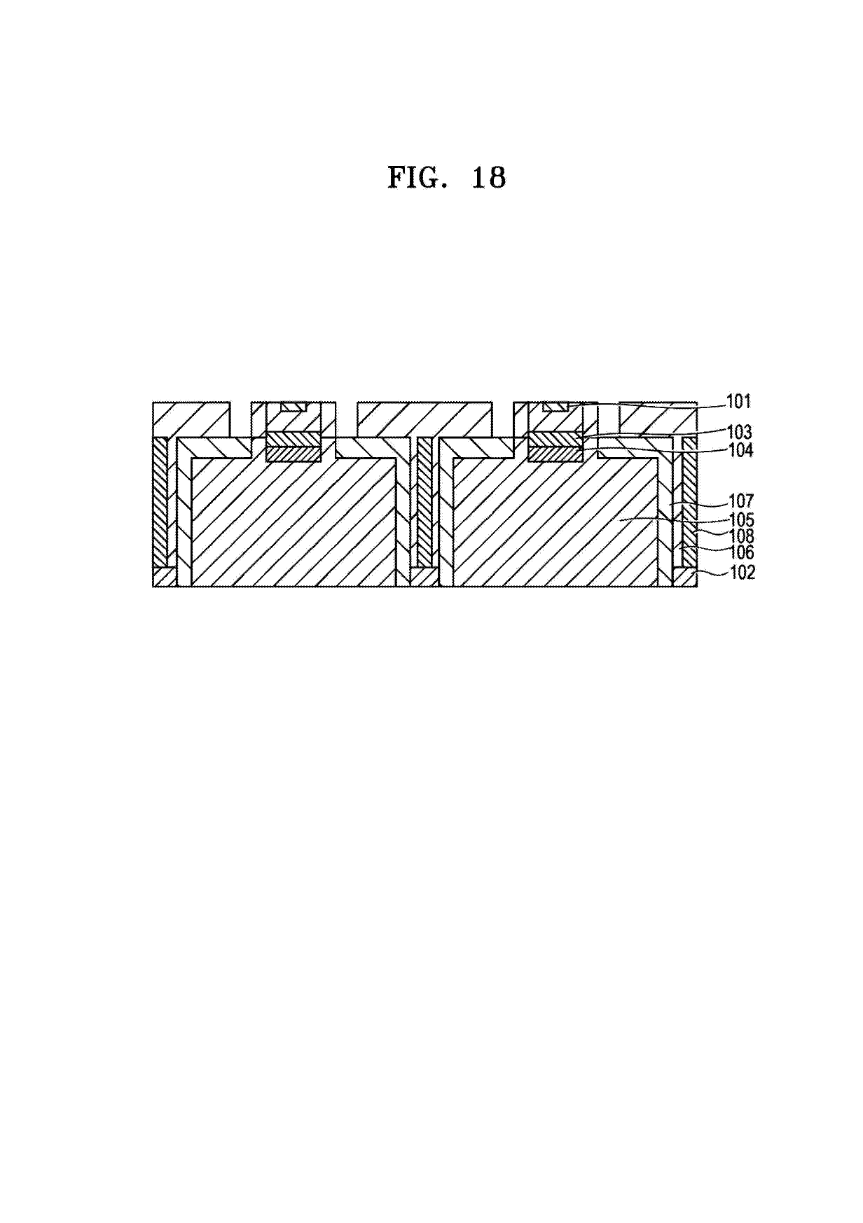

Next, as shown in FIG. 18, a portion constituting the STI of the first insulating film 106 is partially removed by etching using a photolithography technique to expose the P-type semiconductor layer 107.

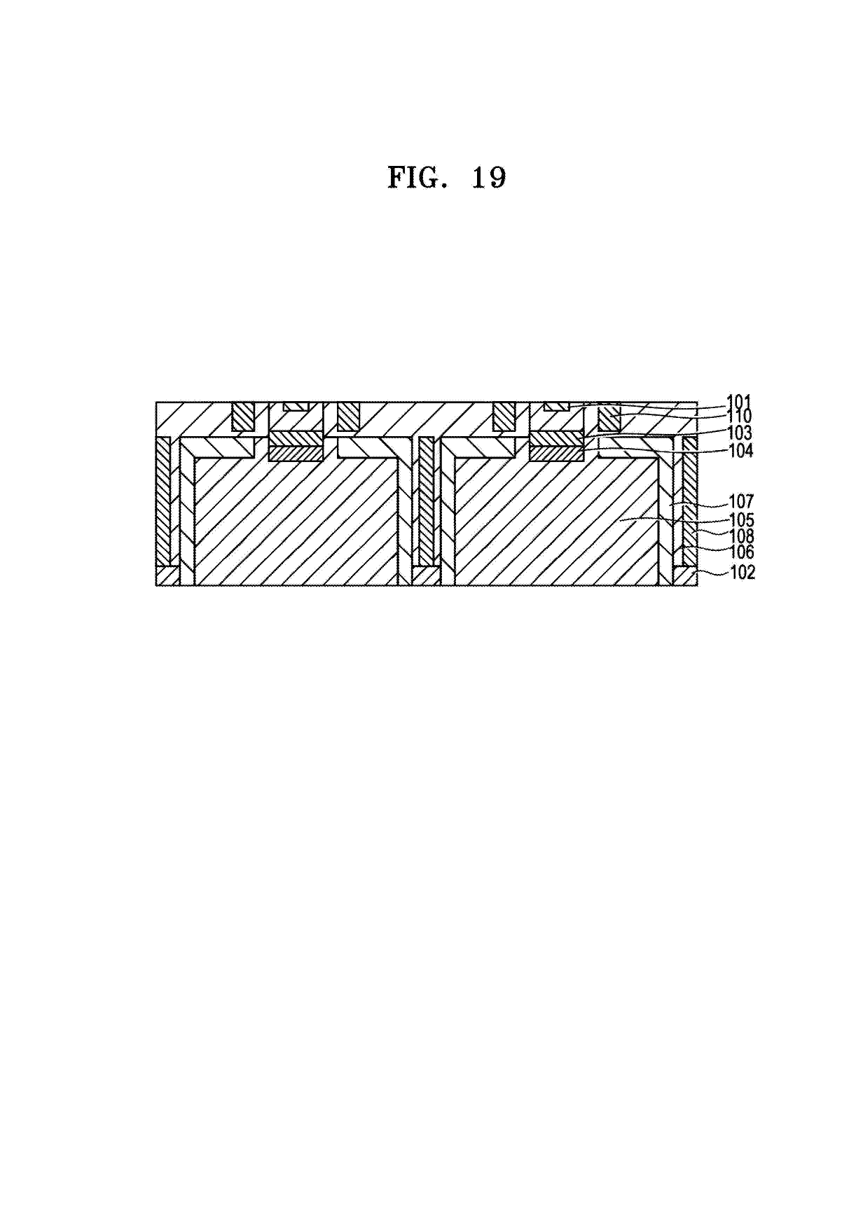

Next, as shown in FIG. 19, a thin film of the first insulating film 106 is formed in a corresponding portion between the subsequently formed gate electrode 110 and the voltage transfer region 501 by depositing silicon oxide therein. Then, polysilicon or metal is deposited to form the gate electrode 110 on the thin film of the formed first insulating film 106.

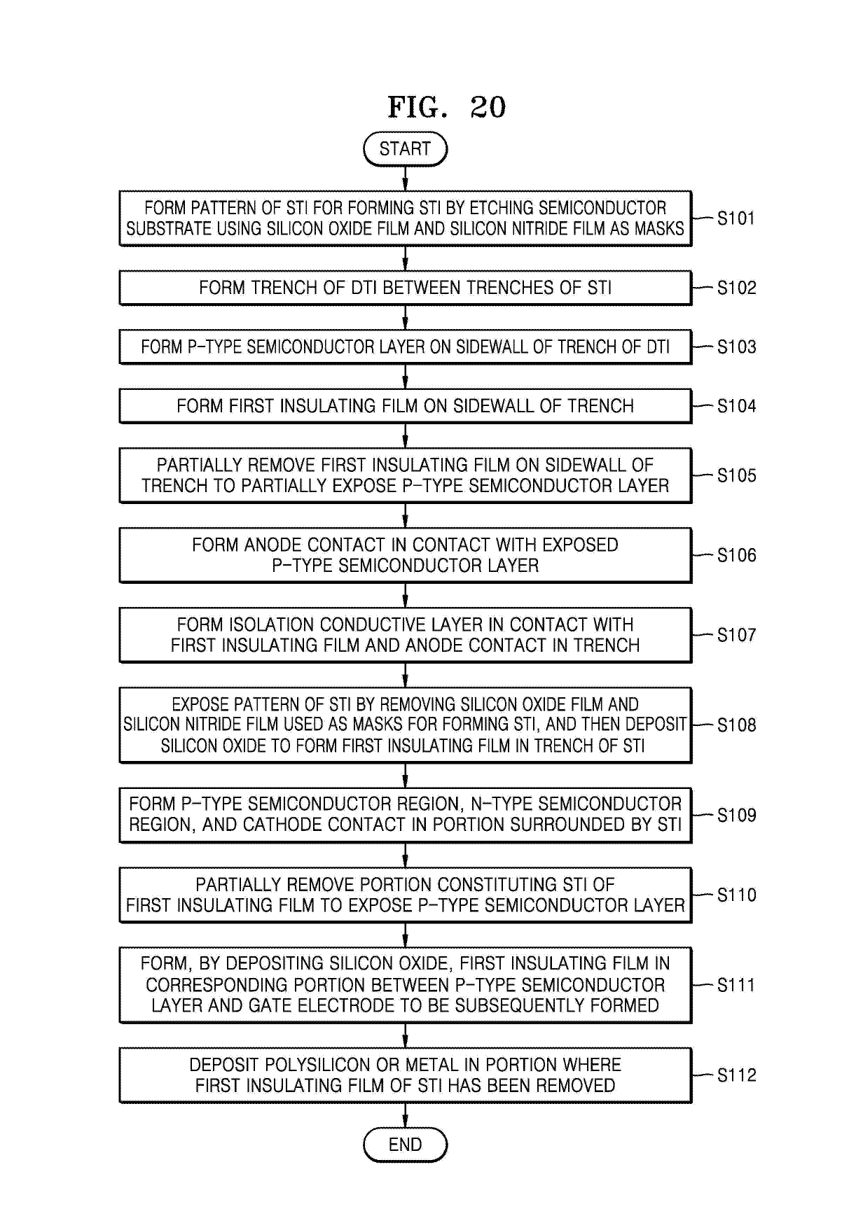

FIG. 20 is a flowchart illustrating main processes of the method of manufacturing the image sensor 1 corresponding to FIGS. 11 to 19.

The pattern of the STI for forming the STI is formed by etching the semiconductor substrate 510 using the silicon oxide film 900 and the silicon nitride film 901 as masks (S101).

Next, the trench 109 for forming the DTI is formed between trenches of the STI (S102).

Next, the P-type semiconductor layer 107 is formed on the sidewall of the trench 109 (S103).

Next, the first insulating film 106 is formed on the sidewall of the trench 109 (S104).

Next, the first insulating film 106 on the sidewall of the trench 109 is partially removed by isotropic etching to partially expose the P-type semiconductor layer 107 (S105), and the anode contact 102 in contact with the exposed P-type semiconductor layer 107 is formed (S106).

Next, the isolation conductive layer 108 in contact with the first insulating film 106 and the anode contact 102 is formed in the trench 109 (S107).

Next, the pattern of the STI is exposed by removing the silicon oxide film 900 and the silicon nitride film 901 used as masks for forming the STI, and then silicon oxide is deposited to form the first insulating film 106 in the trench of the STI (S108). Accordingly, the STI is formed.

Next, the P-type semiconductor region 104, the N-type semiconductor region 103, and the cathode contact 101 are formed in the portion surrounded by the STI (S109).

Next, the portion constituting the STI of the first insulating film 106 is partially removed by etching using the photolithography technique to expose the P-type semiconductor layer 107 (S110).

Next, by depositing silicon oxide, the first insulating film 106 is formed in the corresponding portion between the P-type semiconductor layer 107 and the gate electrode 110 to be subsequently formed (S111).

Next, the gate electrode 110 is formed by depositing polysilicon or metal in a portion where the first insulating film 106 of the STI has been removed in operation S110 (S112).

### Control of Gate Voltage VG

FIG. 21 is a configuration diagram of a system including the SPAD device 100 and the output circuit 40.

The gate voltage generator 80 generates the gate voltage VG based on the feedback signal SFB output from the output circuit 40. The feedback signal SFB may be generated by the signal processing circuit 41 constituting a portion of the output circuit 40. For example, the signal processing circuit 41 generates the feedback signal SFB based on the detection signal VD output from the SPAD pixel 11. Specifically, the signal processing circuit 41 generates the feedback signal SFB based on the count number counted as the number of light particles from the detection signal VD (hereinafter, simply referred to as “count number”). The feedback signal SFB includes a signal for the gate voltage generator 80 to generate the gate voltage VG.

The gate voltage generator 80 may be supplied with a power supply voltage VE for controlling the gate. The power supply VE may be preset as a maximum value of the gate voltage VG. For example, when the anode voltage VA is -20 V, the power supply VE may be any voltage in a range of about -20 V to about +20 V. The gate voltage generator 80 may output, as the gate voltage VG, either the power supply VE or a voltage obtained by attenuating the power supply VE based on the feedback signal SFB. The gate voltage generator 80 may be constituted by a linear regulator or a switching regulator. The gate voltage generator 80 may be configured using at least one of a resistance ladder, a variable constant current source, and a variable resistance device.

The gate voltage generator 80 may be provided for each SPAD pixel 11 as a portion of the SPAD pixel 11.

### Adjustment of Gate Voltage VG Based on Amount of Light Around SPAD Pixel 11

For example, in a dark place where the amount of light around the SPAD pixel 11 is small, the gate voltage VG may be adjusted so that the SPAD pixel is highly sensitive. The signal processing circuit 41 may increase the sensitivity of the SPAD pixel 11 by adjusting the gate voltage VG to a negative voltage having a relatively large absolute value, for example, when the number of counts per certain time is equal to or less than a certain threshold value. In addition, the gate voltage VG may be configured to be set by a user. In this case, for example, a temporary storage device is provided in the output circuit 40, and information of the gate voltage VG set by the user is stored in the temporary storage device. The signal processing circuit 41 may generate the feedback signal SFB for the gate voltage generator 80 to generate the gate voltage VG based on the stored information of the gate voltage VG.

### Adjustment of Gate Voltage VG Based on Temperature of SPAD pixel 11

The breakdown voltage of the SPAD device 100 varies with temperature. For example, the breakdown voltage increases when the temperature increases, and the breakdown voltage decreases when the temperature decreases. Therefore, by adjusting the gate voltage VG based on the temperature, the sensitivity of the SPAD device 100 may be made constant even though the ambient temperature fluctuates. For example, when the temperature measured by a thermometer mounted on the pixel array 10 rises, the gate voltage VG may be adjusted to a negative voltage having a relatively large absolute value to increase the sensitivity of the SPAD device 100, thereby keeping the sensitivity of the SPAD device 100 constant.

### Adjustment of Gate Voltage VG Based on DCR

The gate voltage VG may be adjusted based on the DCR of the SPAD device 100 detected by the output circuit 40. For example, by adjusting the gate voltage VG such that the effective sensitivity of the SPAD device 100, having low photodetection accuracy due to the high DCR, is eliminated, multiplication caused by the DCR of the SPAD device 100 may be suppressed. Accordingly, it is possible to suppress an increase in power consumption due to the multiplication current of the SPAD device 100 having the particularly high DCR resulting from manufacturing variations while maintaining the photodetection accuracy of the entire image sensor 1.

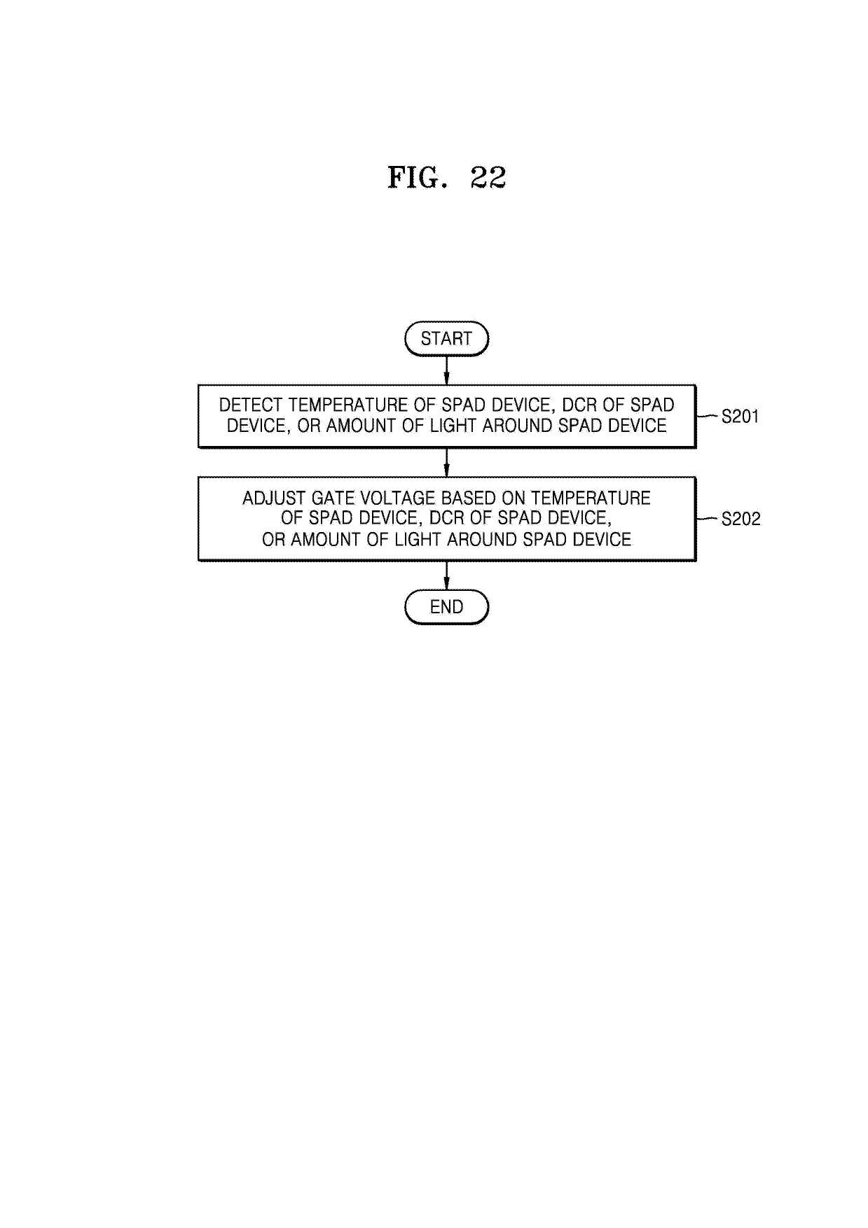

FIG. 22 is a flowchart of a control method of the image sensor 1 for adjusting the gate voltage VG.

The output circuit 40 detects the temperature of the SPAD device 100, the DCR of the SPAD device 100, and/or the amount of light around the SPAD device 100 (S201). These parameters may be obtained individually or in multiple types.

The signal processing circuit 41 adjusts the gate voltage VG generated by the gate voltage generator 80 based on the temperature of the SPAD device 100, the DCR of the SPAD device 100, and/or the amount of light around the SPAD device 100 detected in operation S201 (S202). In the adjustment of the gate voltage VG, the gate voltage VG may be adjusted based on a single parameter or a plurality of parameters.

### Variation 1-1

Variation 1-1 of the first embodiment is described.

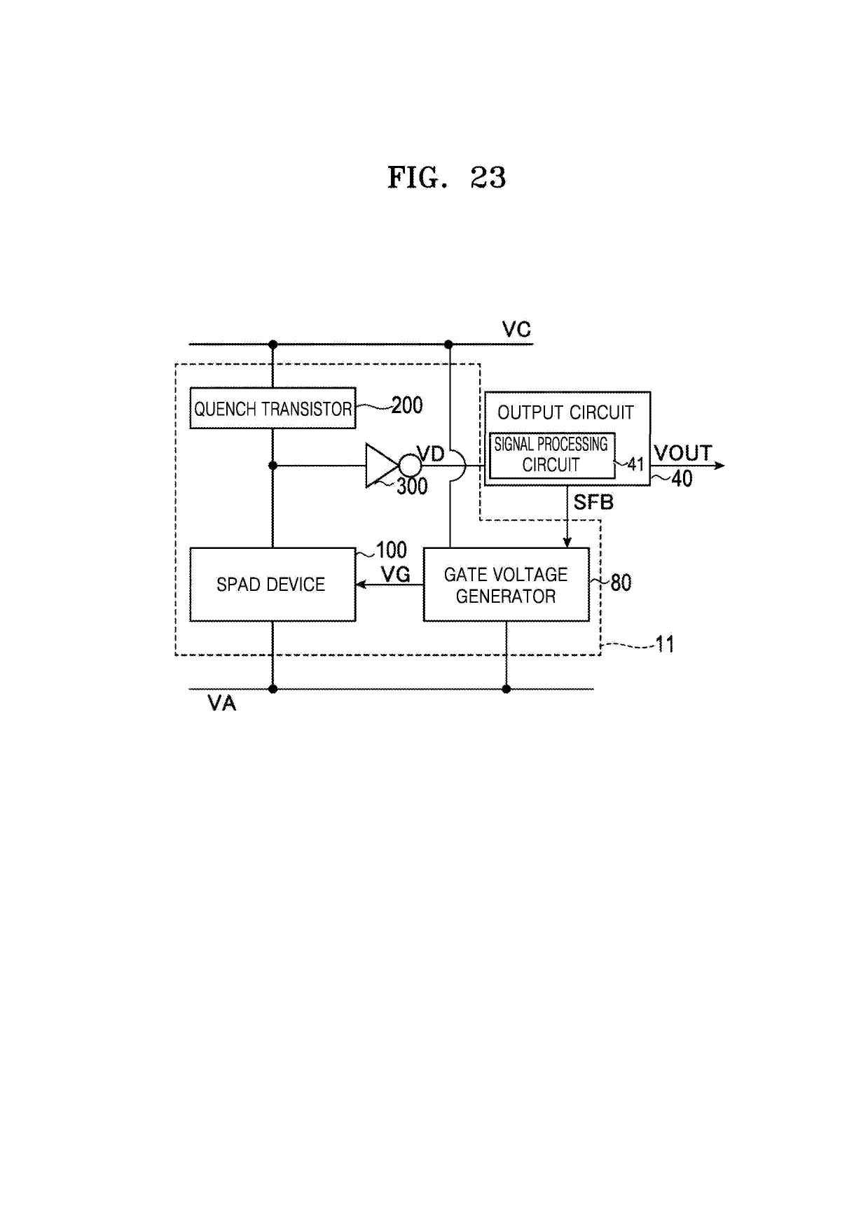

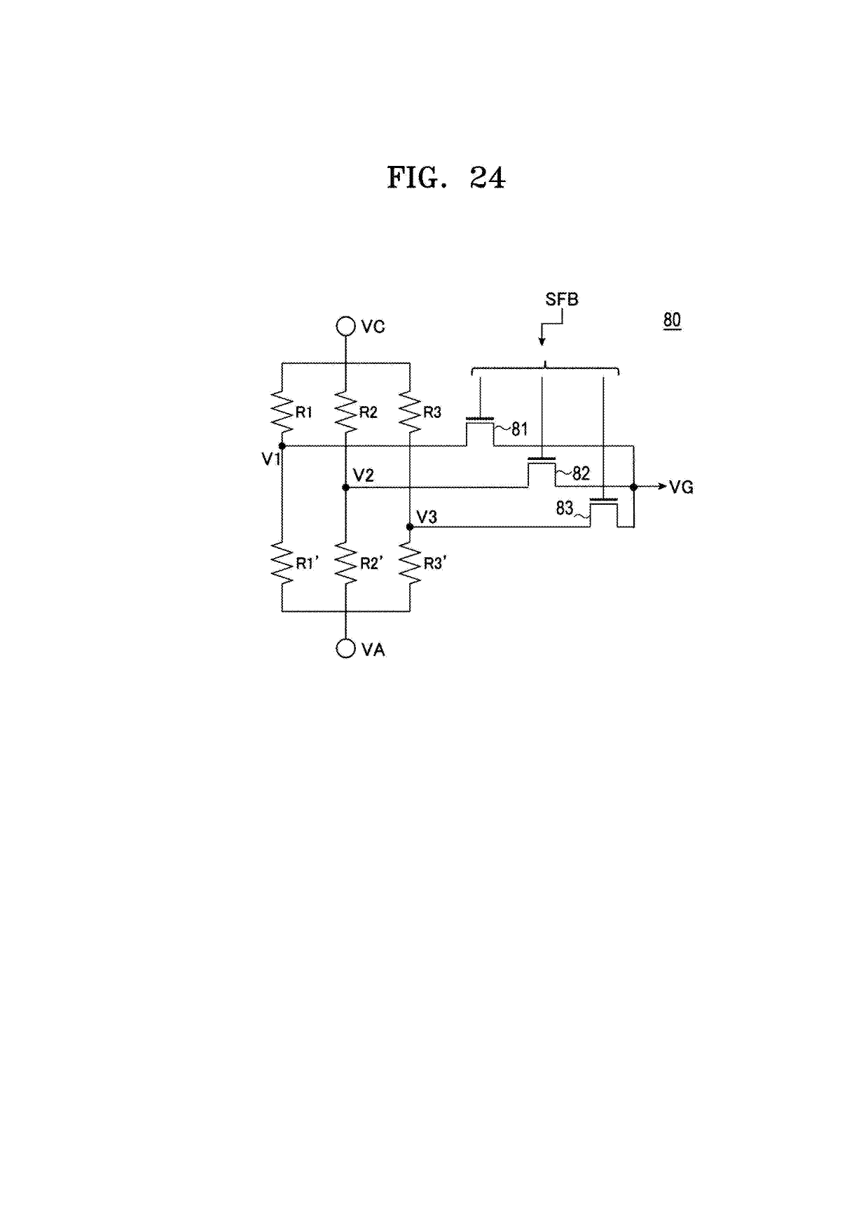

FIG. 23 is a configuration diagram of a system including the SPAD device 100 and the output circuit 40. FIG. 24 is a circuit diagram of the gate voltage generator 80.

Unlike the first embodiment, in variation 1-1, the number of power supplies of the SPAD pixel 11 is two by setting the power supply voltage of the gate voltage generator 80 to the anode voltage VA. In addition, in variation 1-1, the feedback signal SFB includes a parallel digital signal.

As shown in FIG. 24, each gate voltage generator 80 outputs any one of reference voltages V1, V2, and V3 having different values generated by resistance division to each SPAD device 100 as the gate voltage VG based on the feedback signal SFB. The feedback signal SFB is a high or low digital signal for turning on any one of MOS transistors 81, 82, and 83. For example, when a high voltage is input to a gate of the MOS transistor 81 and a low voltage is input to gates of the other MOS transistors 82 and 83, the reference voltage V1 is output from the gate voltage generator 80 as the gate voltage VG. Accordingly, the gate voltage VG may be adjusted.

### Variation 1-2

Variation 1-2 of the first embodiment is described.

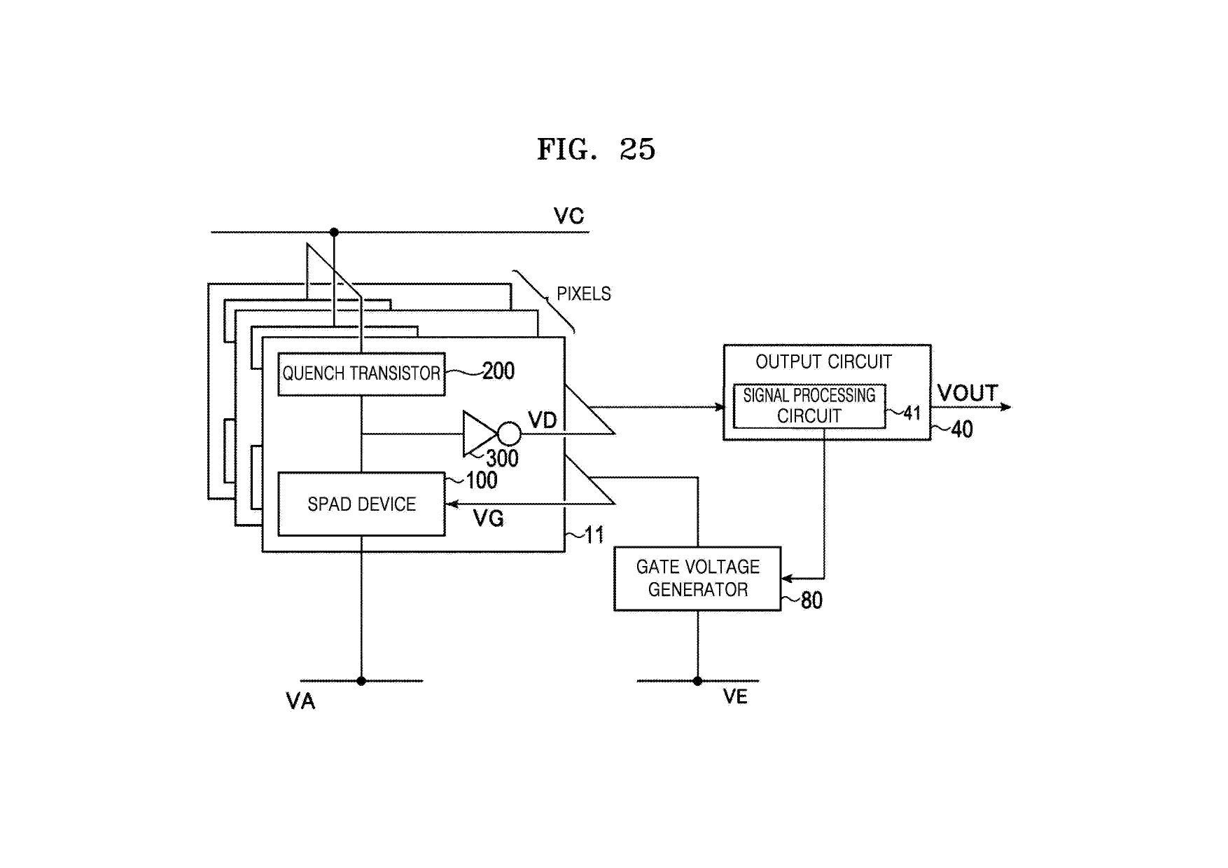

FIG. 25 is a configuration diagram of a system including the SPAD device 100 and the output circuit 40.

In variation 1-2, unlike the first embodiment, one gate voltage generator 80 is provided for multiple SPAD pixels 11. One gate voltage generator 80 may be provided for each of the SPAD pixels 11 or one gate voltage generator 80 may be commonly provided for the SPAD pixels.

As shown in FIG. 25, as one gate voltage generator 80 is provided for the pixels 11, one gate voltage VG is commonly input to the pixels 11. The signal processing circuit 41 generates the feedback signal SFB based on the detection signal VD output from each of the pixels 11. Specifically, the signal processing circuit 41 generates the feedback signal SFB based on a median value or an average value of the count numbers respectively counted from the detection signals VD respectively output from the pixels 11. The gate voltage generator 80 generates the gate voltage VG that is commonly input to the pixels 11 based on the feedback signal SFB.

### Second Embodiment

A second embodiment is described. The difference between the second embodiment and the first embodiment is as follows. In the second embodiment, by relatively increasing the interval or spacing between the end of the first insulating film 106 and the electron multiplication region, the electric field concentration at the end of the first insulating film 106 is alleviated, thereby suppressing edge breakdown. Since the second embodiment is the same as the first embodiment in other respects, redundant descriptions are omitted or simplified.

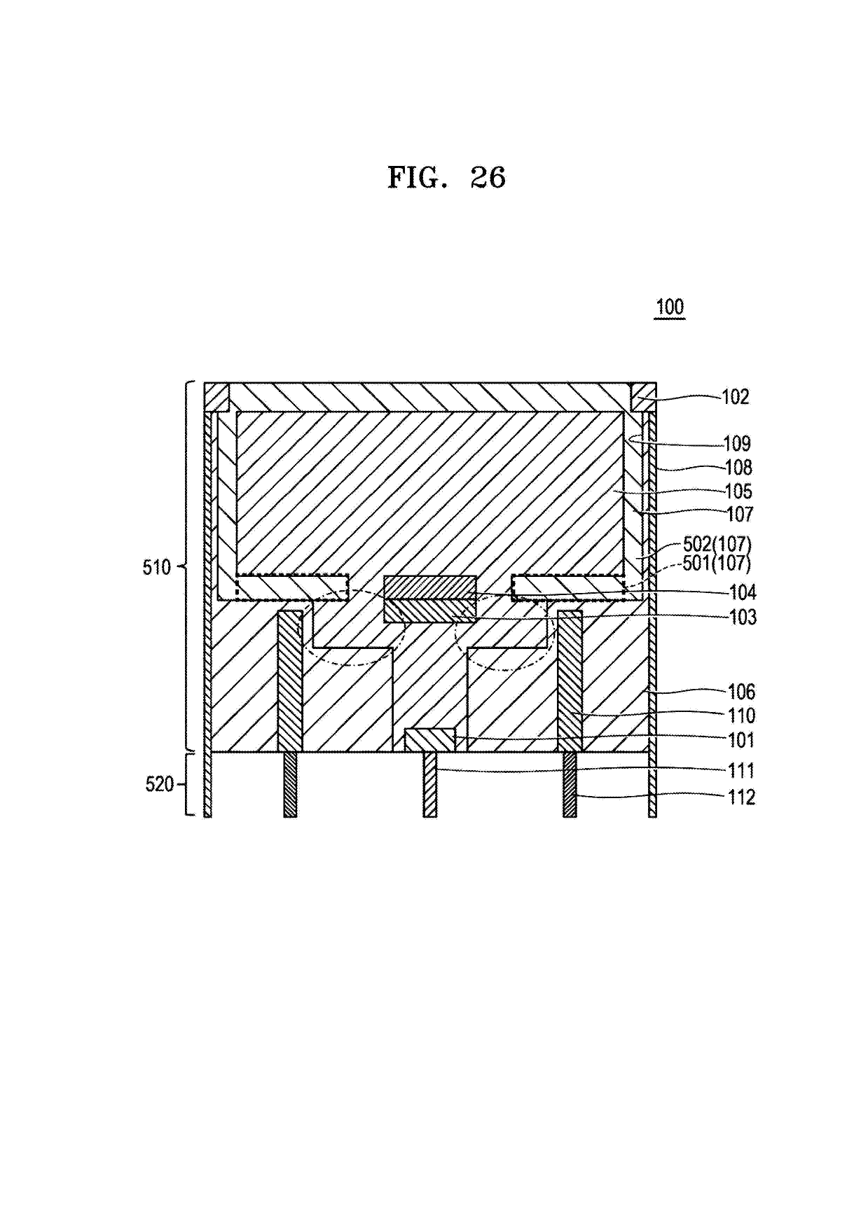

FIG. 26 is a cross-sectional view of the single SPAD device 100.

As shown in portions surrounded by dashed-dotted lines in FIG. 26, the interval of spacing between the end (particularly, a corner) of the first insulating film 106 and the electron multiplication region is relatively far. With such a structure, the electric field concentration at the end of the first insulating film 106 may be alleviated, thereby suppressing the edge breakdown. As a result, DCR may be reduced.

As shown in FIG. 26, the thickness of the first insulating film 106 has a thickness such that the thickness of the first insulating film 106 on an inner side of the gate electrode 110, which faces the cathode contact 101, is less than the thickness of the outer side of the gate electrode 110.

### Third Embodiment

A third embodiment is described. The difference between the third embodiment and the first embodiment is as follows. In the third embodiment, the charge induction region 502, which together with the anode contact 102 forms the anode electrode, has a connection portion connected to the voltage transfer region 501, wherein the cross-sectional area of the connection portion is less than that of other portions. In the third embodiment, the voltage transfer region 501 is aligned with the end of the first insulating film 106 on the side of the cathode contact 101. Furthermore, the length of the gate electrode 110 in the thickness direction of the substrate 510 is less than the width thereof when viewed in the direction perpendicular to the surface of the substrate 510. Since the third embodiment is the same as the first embodiment in other respects, redundant descriptions are omitted or simplified.

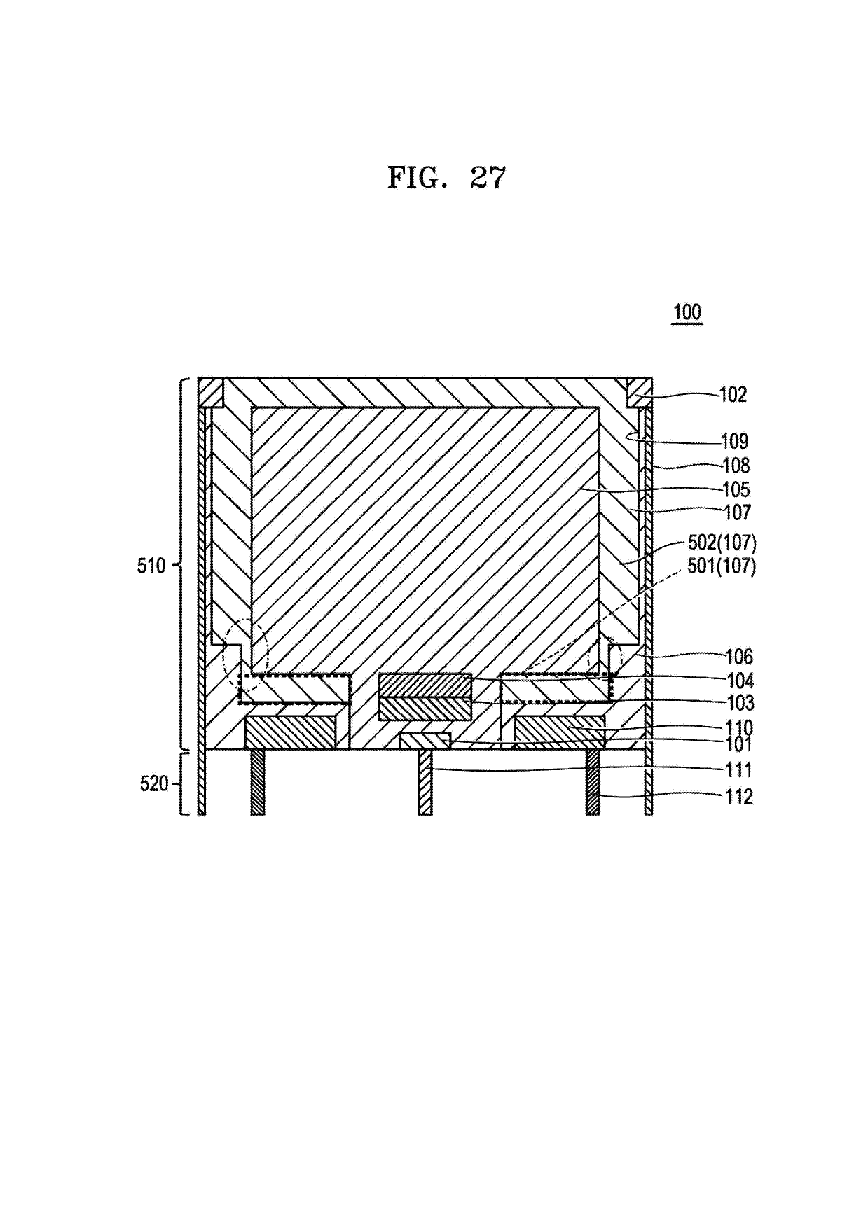

FIG. 27 is a cross-sectional view of the single SPAD device 100.

As shown in portions surrounded by the dashed-dotted lines in FIG. 27, the cross-sectional area of the connection portion of the charge induction region 502 constituting the anode electrode, which is connected to the voltage transfer region 501, is less than that of other portions. The cross-sectional area referred to herein is a cross-sectional area when cut in a direction parallel to the planar direction of the substrate. Accordingly, by weakening the electrical connectivity between the charge induction region 502 and the voltage transfer region 501, it is possible to improve the controllability of the gate voltage VG by the gate electrode 110 in adjusting the degree of voltage transfer from the voltage transfer region 501 to the P-type semiconductor region 104.

In addition, when the voltage transfer region 501 is aligned with the end of the first insulating film 106 on the side of the cathode contact 101, a common mask may be used for forming the voltage transfer region 501 and forming the portion surrounding the gate electrode 110 of the first insulating film 106. Accordingly, it is possible to realize a structure that is resistant to manufacturing variations.

The length of the gate electrode 110 in the thickness direction of the substrate 510 may be less than the width when viewed in the direction perpendicular to the surface of the substrate 510 (the width in the horizontal direction when viewed from the cross-sectional view of FIG. 27). With this configuration, a large volume of the photoelectric conversion region 105 may be ensured and the sensitivity may be increased.

### Variation 3-1

Variation 3-1 of the third embodiment is described.

In the SPAD device 100 of the first embodiment, unlike the third embodiment, the concentration of P-type impurity is less in the connection portion where the voltage transfer region 501 and the charge induction region 502 constituting the anode electrode are connected than in the other portions. Accordingly, by weakening the electrical connectivity between the charge induction region 502 and the voltage transfer region 501, it is possible to improve the controllability of the gate voltage VG by the gate electrode 110 in adjusting the degree of voltage transfer from the voltage transfer region 501 to the P-type semiconductor region 104.

In addition, in the SPAD device 100 of the third embodiment, the concentration of P-type impurity may be made less in the connection portion where the voltage transfer region 501 and the charge induction region 502 constituting the anode electrode are connected than in other portions.

### Fourth Embodiment

A fourth embodiment is described. The difference between the fourth embodiment and the first embodiment is as follows. The fourth embodiment includes an N-type contact layer 113 for discharging an unnecessary charge contributing to an increase in the DCR. Since the fourth embodiment is the same as the first embodiment in other respects, redundant descriptions are omitted or simplified.

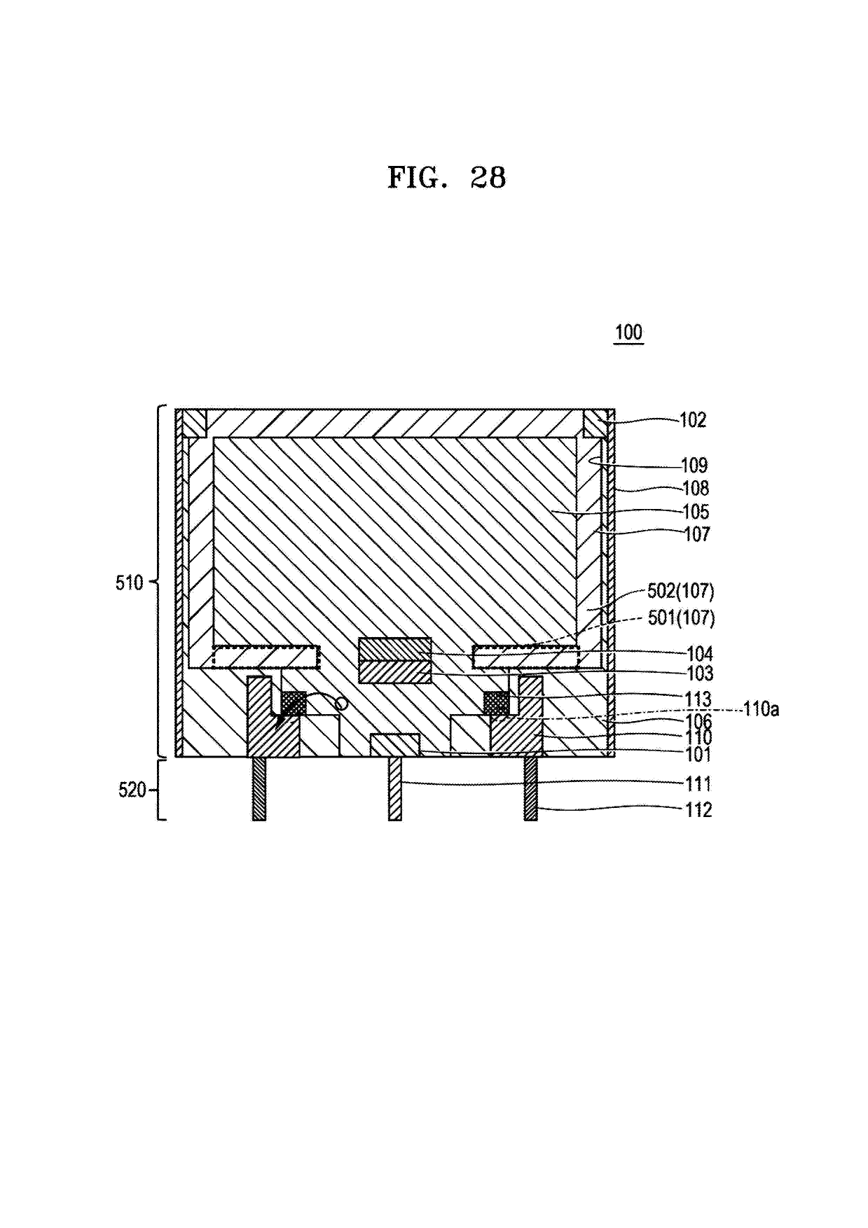

FIG. 28 is a cross-sectional view of the single SPAD device 100.

As shown in FIG. 28, in the fourth embodiment, the N-type contact layer 113 in contact with an uncovered portion 110a of the gate electrode 110 which is not covered by the first insulating film 106 is formed. The uncovered portion 110a is surrounded by the dashed-dotted line of the gate electrode 110 in FIG. 28.

As the unnecessary charge (e.g., an electron) that is indicated by a circle in FIG. 28 and causes the increase in the DCR is attracted to the N-type contact layer 113 by applying a constant voltage as the gate voltage VG, the unnecessary charge may be discharged through the gate electrode 110.

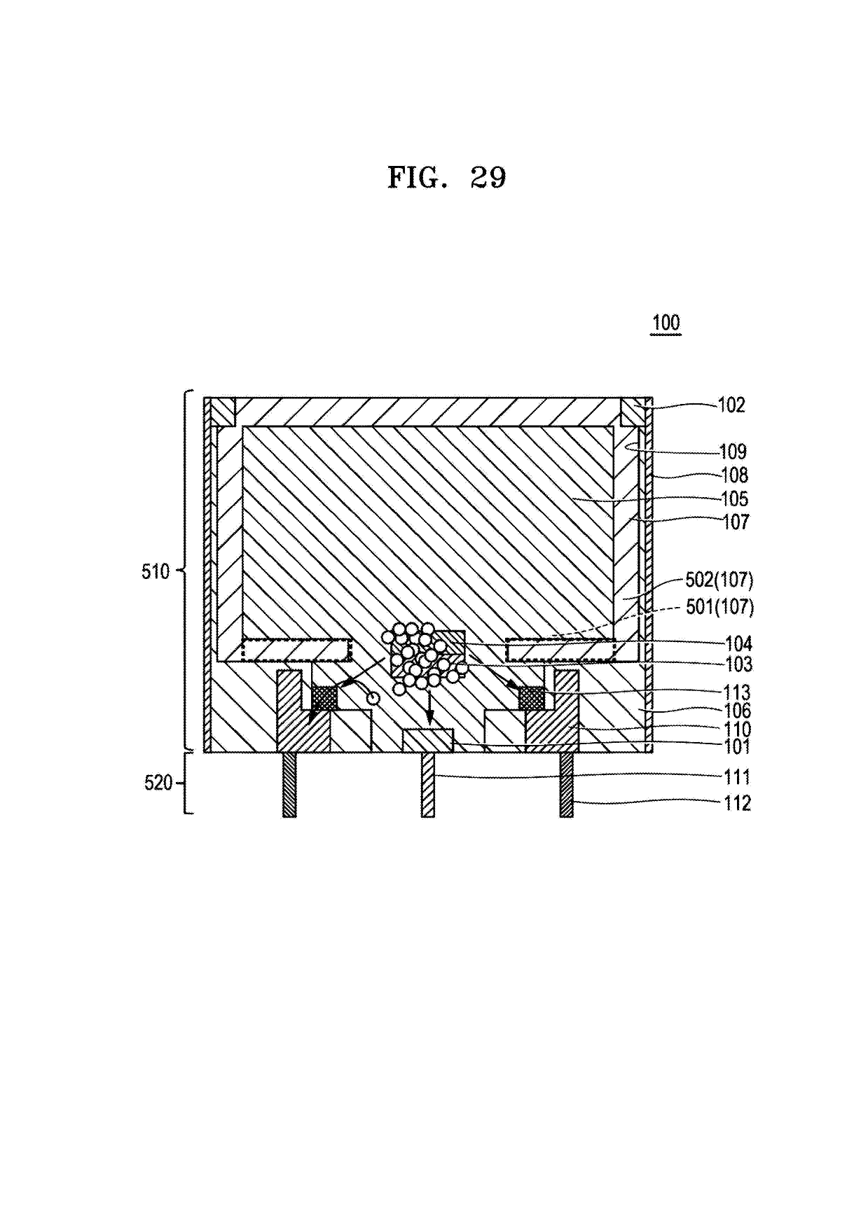

FIG. 29 is a diagram illustrating that electrons multiplied in the electron multiplication region are discharged through the N-type contact layer 113.

The N-type contact layer 113 also has a function of rapidly discharging some of the multiplied electrons in parallel in the electron multiplication region. Each of these electrons is indicated by a circle in FIG. 29. Accordingly, the recharge operation in the SPAD pixel 11 is promoted, thereby enabling the SPAD device 100 to rapidly return to a state capable of multiplication.

### Variation 4-1

Variation 4-1 of the fourth embodiment is described.

In variation 4-1, unlike the fourth embodiment, the uncovered portion 110a of the gate electrode 110, which is not covered by the first insulating film 106, is formed on the outer periphery of the gate electrode 110. For example, the N-type contact layer 113 formed in the uncovered portion 110a is also formed on the outer periphery of the gate electrode 110.

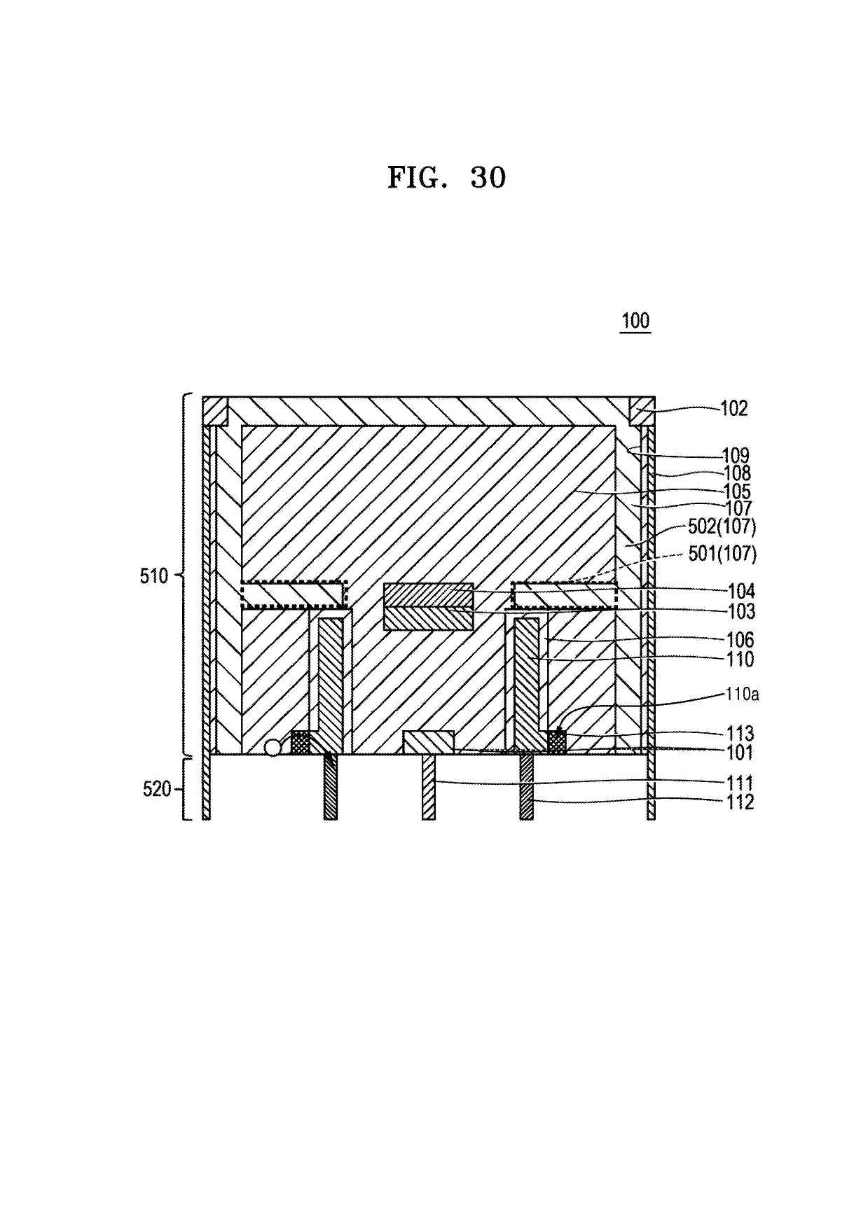

FIG. 30 is a cross-sectional view of the single SPAD device 100.

As shown in FIG. 30, the N-type contact layer 113 in contact with the uncovered portion 110a which is not covered by the first insulating film 106 on the outer periphery of the gate electrode 110 is formed. The uncovered portion 110a of the gate electrode 110 that is not covered by the first insulating film 106 is formed on the opposite side (outer periphery) of the gate electrode 110 to the electron multiplication region, and the N-type contact layer 113 in contact with the uncovered portion 110a is also formed on the opposite side (outer periphery) of the gate electrode 110 to the electron multiplication region.

The unnecessary charge (e.g., electron) that is indicated by a circle in FIG. 30 and causes the increase in the DCR is attracted to the N-type contact layer 113 by applying a constant voltage as the gate voltage VG and may be discharged through the gate electrode 110.

### Fifth Embodiment

A fifth embodiment is described. The difference between the fifth embodiment and the first embodiment is as follows. In the fifth embodiment, the anode contact 102 is provided on the surface of the semiconductor substrate 510 opposite to the light incident surface thereof. Since the fifth embodiment is the same as the first embodiment in other respects, redundant descriptions are omitted or simplified.

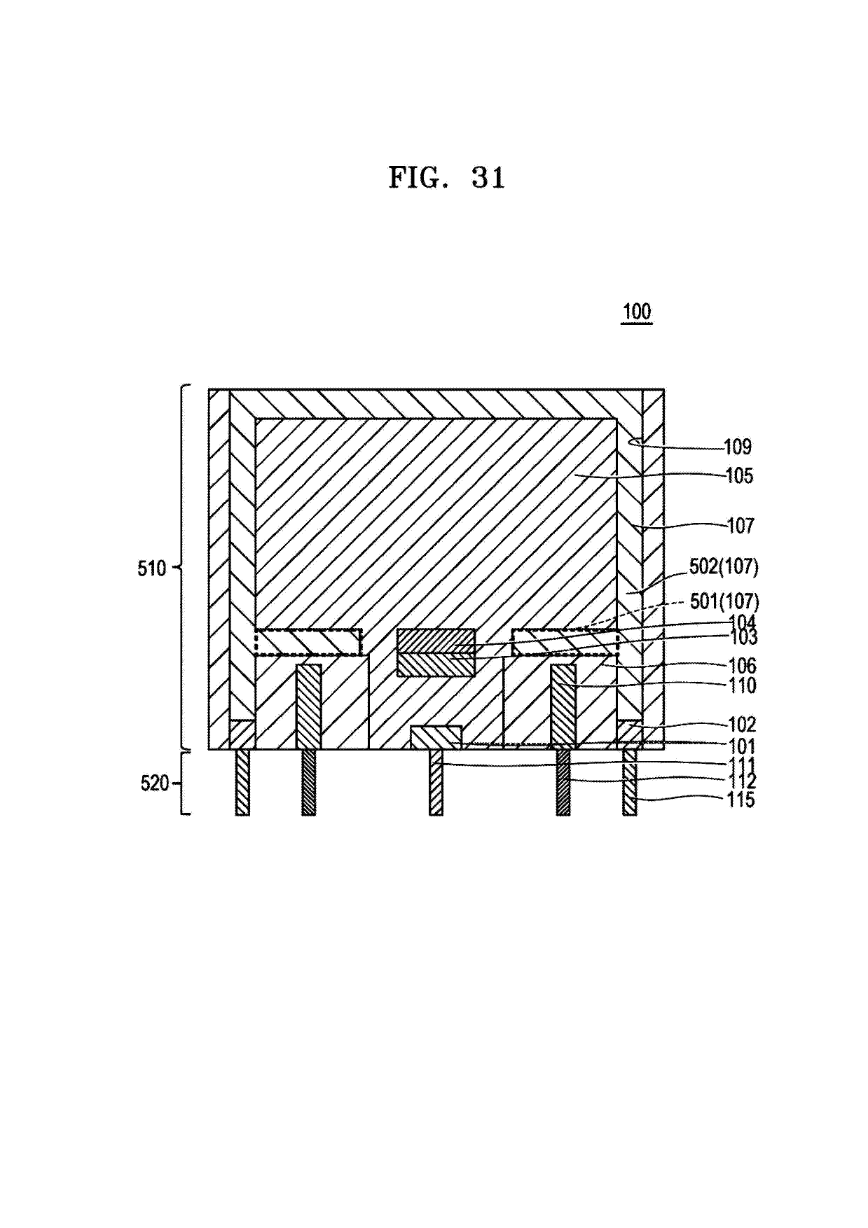

FIG. 31 is a cross-sectional view of a single SPAD device 100.

As shown in FIG. 31, in the fifth embodiment, the anode contact 102 is provided on the surface of the semiconductor substrate 510 opposite to the light incident surface thereof. The anode contact 102 is connected to the anode wiring 115 formed in the wiring layer 520.

### Sixth Embodiment

A sixth embodiment is described. The difference between the sixth embodiment and the first embodiment is as follows. In this embodiment, the anode contact 102 is provided on the surface of the semiconductor substrate 510 opposite to the light incident surface thereof. In the fifth embodiment, the cathode contact 101 is embedded in the first insulating film 106 and is in contact with the N-type semiconductor region 103. Since the fifth embodiment is the same as the first embodiment in other respects, redundant descriptions are omitted or simplified.

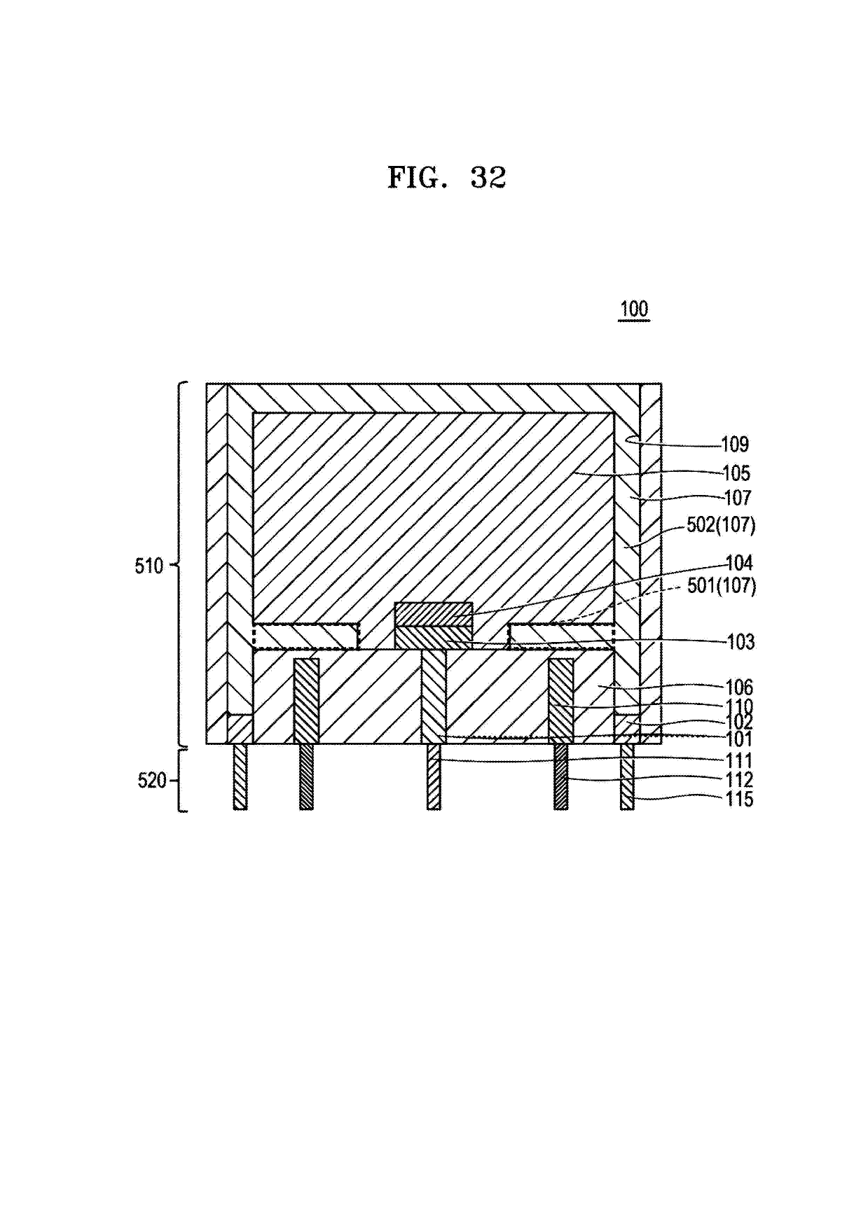

FIG. 32 is a cross-sectional view of a single SPAD device 100.

As shown in FIG. 32, in the fifth embodiment, the anode contact 102 is provided on the surface of the semiconductor substrate 510 opposite to the light incident surface thereof. The anode contact 102 is connected to the anode wiring 115 formed in the wiring layer 520. In addition, in the fifth embodiment, the cathode contact 101 is embedded in the first insulating film 106 and is in contact with the N-type semiconductor region 103.

The embodiments exhibit the following effects.

A photoelectric conversion device of a photodetector includes a cathode electrode, an anode electrode arranged around the cathode electrode, an electron multiplication region in which a first region of a first conductivity type is bonded to a second region of a second conductivity type, a voltage transfer region of the first conductivity type arranged around the cathode electrode and configured to transmit a voltage of the anode electrode to the first region, and a gate electrode arranged around the cathode electrode and facing the voltage transfer region with an insulating film arranged therebetween. Then, the degree of voltage transfer from the voltage transfer region to the first region is adjusted by the gate voltage applied to the gate electrode. Accordingly, it is possible to improve the photodetection sensitivity, without increasing the DCR, while reducing variations in the photodetection sensitivity due to the manufacturing variations.

In addition, the same voltage as the voltage applied to the anode electrode or the different voltage therefrom is applied to the gate electrode. Accordingly, the gate voltage may be more flexibly adjusted, the photodetection sensitivity may be effectively improved, and the variations in the photodetection sensitivity due to the manufacturing variations may be reduced.

In addition, the gate electrode is formed in an annular shape surrounding the cathode electrode when viewed in the direction perpendicular to the surface of the substrate. As a result, it is possible to further improve the photodetection sensitivity while reducing the variations in the photodetection sensitivity due to the manufacturing variations.

In addition, the gate electrode includes polysilicon or metal. Accordingly, it is possible to more easily improve the photodetection sensitivity while reducing the variations in the photodetection sensitivity due to the manufacturing variations.

In addition, the length of the gate electrode in the thickness direction of the substrate is made greater than the width of the gate electrode when viewed in the direction perpendicular to the surface of the substrate. As a result, a structure resistant to the manufacturing variations may be easily obtained.

In addition, the length of the gate electrode in the thickness direction of the substrate is less than the width of the gate electrode when viewed in the direction perpendicular to the surface of the substrate. Accordingly, by forming a structure in which the end of the insulating film surrounding the voltage transfer region is aligned with the gate electrode, a common mask may be used for forming the voltage transfer region and forming the portion surrounding the gate electrode of the insulating film. Accordingly, it is possible to realize a structure that is resistant to the manufacturing variations.

In addition, the insulating film includes a silicon oxide film. Accordingly, it is possible to more easily improve the photodetection sensitivity, without increasing the DCR, while reducing the variations in the photodetection sensitivity due to the manufacturing variations.

In addition, the insulating film is brought into contact with the voltage transfer region. Accordingly, it is possible to more easily improve the photodetection sensitivity, without increasing the DCR, while reducing the variations in the photodetection sensitivity due to the manufacturing variations.

In addition, the insulating film is brought into contact with the isolation portion that separates the photoelectric conversion devices from each other. Accordingly, it is possible to more easily enhance the device isolation effect and improve the photodetection sensitivity, without increasing the DCR, while reducing the variations in the photodetection sensitivity due to the manufacturing variations.

Furthermore, the gate electrode is formed to surround the cathode electrode when viewed in the direction perpendicular to the surface of the substrate, and the insulating film is formed with the same length in the thickness direction of the substrate on the inner side and the outer side of the gate electrode. Accordingly, it is possible to more easily improve the device isolation effect and improve the photodetection sensitivity, without increasing the DCR, while reducing the variations in the photodetection sensitivity due to the manufacturing variations.

In addition, the gate electrode is formed to surround the cathode electrode when viewed in the direction perpendicular to the surface of the substrate, and the insulating film is formed with the length in the thickness direction of the substrate greater on the outer side than on the inner side of the gate electrode. Accordingly, as the interval between the end of the insulating film and the electron multiplication region becomes relatively large, the electric field concentration at the end of the insulating film may be alleviated to suppress the edge breakdown. As a result, the DCR may be further reduced.

In addition, the contact layer of the second conductivity type in contact with an uncovered portion of the gate electrode that is not covered by the insulating film is provided. Accordingly, the unnecessary charge contributing to an increase in the DCR may be discharged through the gate electrode, whereby the DCR may be further reduced.

In addition, the anode contact, to which the anode voltage is supplied, of the anode electrode is formed on the sidewall of the isolation portion that separates the photoelectric conversion devices from each other. Accordingly, the DCR may be effectively and flexibly reduced.

In addition, the anode electrode is formed so that the cross-sectional area of the connection portion connected to the voltage transfer region is less than that of the other portions or so that the impurity concentration of the first conductivity type in the connection portion is less than that in the other portions. Accordingly, by weakening the electrical connectivity between the charge induction region and the voltage transfer region, it is possible to improve the controllability of the gate voltage by the gate electrode in adjusting the degree of voltage transfer from the voltage transfer region to the electron multiplication region.

In addition, the gate voltage controller that adjusts the gate voltage to be applied to the gate electrode based on the detected temperature of the photoelectric conversion device is provided. Accordingly, the photodetection sensitivity may be made constant even when the ambient temperature fluctuates.

In addition, the gate voltage controller that adjusts the gate voltage to be applied to the gate electrode based on the detected DCR of the photoelectric conversion device is provided. Accordingly, for example, by adjusting the gate voltage so that the effective sensitivity of the photoelectric conversion device having the high DCR and low photodetection accuracy is lost, multiplication of the dark current of the photoelectric conversion device may be suppressed. Accordingly, it is possible to suppress an increase in power consumption caused by the photoelectric conversion device with the particularly high DCR due to the manufacturing variations while maintaining the overall photodetection accuracy of the photodetector.

In addition, the gate voltage controller that adjusts the gate voltage to be applied to the gate electrode based on the detected amount of light around the photoelectric conversion device is provided. Thus, for example, the photodetection sensitivity may be increased in a dark place where the amount of light around the photoelectric conversion device is small.

In addition, the gate voltage applied to the gate electrode is adjusted for each photoelectric conversion device. Accordingly, the photodetection sensitivity of all the photoelectric conversion devices may be maintained at a high level.

In addition, the gate voltage controller is configured using the linear regulator. Accordingly, it is possible to more easily improve the photodetection sensitivity while reducing the variations in the photodetection sensitivity due to the manufacturing variations.

In addition, the gate voltage controller is configured using a switching regulator. Accordingly, it is possible to more easily improve the photodetection sensitivity while reducing the variations in the photodetection sensitivity due to the manufacturing variations.

In addition, the gate voltage controller is configured using the resistance ladder. Accordingly, it is possible to more easily improve the photodetection sensitivity while reducing the variations in the photodetection sensitivity due to the manufacturing variations.

In addition, the gate voltage controller is configured using a variable constant current source. Accordingly, it is possible to more easily improve the photodetection sensitivity while reducing the variations in the photodetection sensitivity due to the manufacturing variations.

In addition, the gate voltage controller is configured using a variable resistance device. Accordingly, it is possible to more easily improve the photodetection sensitivity while reducing the variations in the photodetection sensitivity due to the manufacturing variations.

In addition, a photodetector includes a plurality of photoelectric conversion devices wherein the photoelectric conversion device includes the cathode electrode, the anode electrode arranged around the cathode electrode, the electron multiplication region in which the first region of the first conductivity type is bonded to the second region of the second conductivity type, the voltage transfer region of the first conductivity type arranged around the cathode electrode and configured to transmit a voltage of the anode electrode to the first region of the electron multiplication region, and the gate electrode arranged around the anode electrode and facing the voltage transfer region with the insulating film arranged therebetween, the photodetector being configured to adjust the degree of voltage transfer from the voltage transfer region to the first region by the gate voltage applied to the gate electrode, wherein the photodetector is controlled to detect the temperature of the photoelectric conversion device, the DCR of the photoelectric conversion device, or the amount of light around the photoelectric conversion device, and adjust the gate voltage based on the detected temperature of the photovoltaic converter, the DCR of photoelectric conversion device or the amount of light around photoelectric conversion device. Accordingly, the sensitivity of the photoelectric conversion device may be kept constant, and an increase in power consumption may be suppressed.

While the inventive concept has been particularly shown and described with reference to embodiments thereof, it will be understood that various changes in form and details may be made therein without departing from the spirit and scope of the following claims.

What is claimed is:

1. A photodetector comprising a plurality of photoelectric conversion devices, wherein each of the photoelectric conversion device comprises:
a cathode electrode;
an anode electrode arranged around the cathode electrode;
an electron multiplication region comprising a first region of a first conductivity type is in contact with a second region of a second conductivity type;
a voltage transfer region of the first conductivity type arranged around the cathode electrode and configured to transfer a voltage of the anode electrode to the first region of the electron multiplication region; and
a gate electrode arranged around the cathode electrode and facing the voltage transfer region with an insulating film arranged between the gate electrode and the cathode electrode,
wherein a degree of voltage transfer from the voltage transfer region to the first region is adjustable based on a gate voltage applied to the gate electrode.

2. The photodetector of claim 1, wherein the anode electrode and the cathode electrode are configured so that a voltage applied to the anode electrode is the same as the gate voltage applied to the gate electrode.

3. The photodetector of claim 1, wherein the anode electrode and the cathode electrode are configured so that a voltage applied to the anode electrode is different from the gate voltage applied to the gate electrode.

4. The photodetector of claim 1, wherein the photoelectric conversion device is formed on a substrate, and the gate electrode is formed in an annular shape surrounding the cathode electrode when viewed in a direction perpendicular to a surface of the substrate.

5. The photodetector of claim 1, wherein the gate electrode comprises polysilicon or metal.

6. The photodetector of claim 1, wherein the photoelectric conversion device is formed on a substrate, and a length of the gate electrode in a thickness direction of the substrate is greater than a width of the gate electrode when viewed in a direction perpendicular to a surface of the substrate.

7. The photodetector of claim 1, wherein the photoelectric conversion device is formed on a substrate, and a length of the gate electrode in a thickness direction of the substrate is less than a width of the gate electrode when viewed in a direction perpendicular to a surface of the substrate.

8. The photodetector of claim 1, wherein the insulating film comprises a silicon oxide film.

9. The photodetector of claim 1, wherein the insulating film is in contact with the voltage transfer region.

10. The photodetector of claim 1, further comprising an isolation portion that separates adjacent photoelectric conversion devices, wherein the insulating film is in contact with an isolation portion.

11. The photodetector of claim 1, wherein:
the photoelectric conversion device is formed on a substrate,
the gate electrode surrounds the cathode electrode when viewed in a direction perpendicular to a surface of the substrate, and
a length of the insulating film in a thickness direction of the substrate is the same on an inner side and an outer side of the gate electrode.

12. The photodetector of claim 1, wherein the photoelectric conversion device is formed on a substrate,
the gate electrode surrounds the cathode electrode when viewed in a direction perpendicular to a surface of the substrate, and
a length of the insulating film in a thickness direction of the substrate is greater on an outer side than on an inner side of the gate electrode.

13. The photodetector of claim 1, further comprising a contact layer of the second conductivity type in contact with a portion of the gate electrode not covered by the insulating film.

14. The photodetector of claim 1, wherein an anode contact of the anode electrode is formed on a sidewall of an isolation portion that separates adjacent photoelectric conversion devices of the photoelectric conversion devices.

15. The photodetector of claim 1, wherein the anode electrode comprises a body portion and a connection portion connected to the voltage transfer region, and the connection portion has a smaller cross-sectional area than the body portion.

16. The photodetector of claim 1, wherein the anode electrode comprises a connection portion connected to the voltage transfer region, and the connection portion has a lower concentration of first conductivity-type impurities than other portions of the anode electrode.

17. The photodetector of claim 1, further comprising:
a gate voltage generator configured to generate the gate voltage and provide the gate voltage to the gate electrode;
an output circuit configured to generate a feedback signal based on a detection signal output from the photoelectric conversion device,
wherein the gate voltage generator is configured to dynamically adjust the generated gate voltage based on the feedback signal.

18. A photodetector comprising a plurality of photoelectric conversion devices, wherein each of the photoelectric conversion devices comprises:
a cathode electrode;
an anode electrode arranged around the cathode electrode;
an electron multiplication region comprising a first region of a first conductivity type in contact with a second region of a second conductivity type;
a voltage transfer region of the first conductivity type arranged around the cathode electrode and configured to transfer a voltage of the anode electrode to the first region of the electron multiplication region;
a gate electrode arranged around the cathode electrode and facing the voltage transfer region with an insulating film arranged therebetween; and
a gate voltage controller configured to adjust a gate voltage applied to the gate electrode, based on one or more of a detected temperature of the photoelectric conversion device, a dark count rate (DCR) of the photoelectric conversion device, and an amount of light around the photoelectric conversion device,
wherein a degree of voltage transfer from the voltage transfer region to the first region is adjustable based on the gate voltage applied to the gate electrode.

19. The photodetector of claim 18, wherein the gate voltage controller is configured to adjust the gate voltage applied to the gate electrode for each of the photoelectric conversion devices.

20. A control method of a photodetector comprising a plurality of photoelectric conversion devices, wherein each of the photoelectric conversion device comprises:
a cathode electrode;
an anode electrode arranged around the cathode electrode;
an electron multiplication region comprising a first region of a first conductivity type in contact with a second region of a second conductivity type;
a voltage transfer region of the first conductivity type arranged around the cathode electrode and configured to transfer a voltage of the anode electrode to the first region of the electron multiplication region; and
a gate electrode arranged around the cathode electrode and facing the voltage transfer region with an insulating film arranged therebetween,
wherein a degree of voltage transfer from the voltage transfer region to the first region is adjusted by a gate voltage applied to the gate electrode, the control method comprising:
(a) detecting:
a temperature of a first photoelectric conversion device of the plurality of photoelectric conversion devices,
a dark count rate (DCR) of the first photoelectric conversion device, and/or
an amount of light around the first photoelectric conversion device; and
(b) adjusting the gate voltage, based on:
the detected temperature of the first photoelectric conversion device,
the detected DCR of the first photoelectric transfer device, and/or
the detected amount of light around the first photoelectric conversion device.
